(19) United States
(12) Patent Application Publication
(10) Pub. No.: US 2023/0413655 A1
(43) Pub. Date: Dec. 21, 2023

(54) EVAPORATION DEVICE AND EVAPORATION METHOD

(71) Applicant: Japan Display Inc., Tokyo (JP)

(72) Inventor: Atsushi TAKEDA, Tokyo (JP)

(73) Assignee: Japan Display Inc., Tokyo (JP)

(21) Appl. No.: 18/336,036

(22) Filed: Jun. 16, 2023

(30) Foreign Application Priority Data
Jun. 21, 2022 (JP) 2022-099797

(51) Int. Cl. H10K 71/16

(52) U.S. Cl. CPC H10K 71/16

(57) ABSTRACT

According to one embodiment, an evaporation device includes a first chamber group including a plurality of evaporation chambers arranged in line in a first conveyance direction, a second chamber group including a plurality of evaporation chambers arranged in line in a second conveyance direction, a first rotation chamber which is connected to a first evaporation chamber located at a upstream position in the first conveyance direction and a second evaporation chamber located at a downstream position in the second conveyance direction, and a second rotation chamber which is connected to a third evaporation chamber located at a downstream position in the first conveyance direction and a fourth evaporation chamber located at a upstream position in the second conveyance direction.

### CROSS-REFERENCE TO RELATED APPLICATIONS

This application is based upon and claims the benefit of priority from Japanese Patent Application No. 2022-099797, filed Jun. 21, 2022, the entire contents of which are incorporated herein by reference.

### FIELD

Embodiments described herein relate generally to an evaporation device and an evaporation method.

### BACKGROUND

Recently, display devices to which an organic light emitting diode (OLED) is applied as a display element have been put into practical use. This display element comprises a pixel circuit including a thin-film transistor, a lower electrode connected to the pixel circuit, an organic layer which covers the lower electrode, and an upper electrode which covers the organic layer. The organic layer includes functional layers such as a hole transport layer and an electron transport layer in addition to a light emitting layer.

In a manufacturing device for forming the organic layer including the above functional layers, there is demand for the reduction in the cost and the reduction in the installation space.

### BRIEF DESCRIPTION OF THE DRAWINGS

FIG. 1 is a diagram showing a configuration example of a display device DSP.

FIG. 2 is a diagram showing an example of the layout of subpixels SP1, SP2 and SP3.

FIG. 3 is a schematic cross-sectional view of the display device DSP along the A-B line of FIG. 2.

FIG. 4 is a flow diagram for explaining an example of the manufacturing method of the display device DSP.

FIG. 5 is a diagram for explaining the manufacturing method of the display device DSP.

FIG. 6 is a diagram for explaining the manufacturing method of the display device DSP.

FIG. 7 is a diagram for explaining the manufacturing method of the display device DSP.

FIG. 8 is a diagram for explaining the manufacturing method of the display device DSP.

FIG. 9 is a diagram for explaining the manufacturing method of the display device DSP.

FIG. 10 is a diagram showing an example of the configuration of display elements 201 to 203.

FIG. 11 is a diagram showing another example of the configuration of the display elements 201 to 203.

FIG. 12 is a diagram for explaining a configuration example of an evaporation device 100.

FIG. 13 is a diagram for explaining the conveyance chamber 120 shown in FIG. 12.

FIG. 14 is a diagram for explaining the substrate attachment/detachment chamber 130 and the first rotation chamber 140 shown in FIG. 12.

FIG. 15 is a diagram for explaining the evaporation portion 150 shown in FIG. 12.

FIG. 16 is a diagram for explaining the process of forming the organic layer OR1 and the upper electrode UE1 of the display element 201 shown in FIG. 10 by the evaporation device 100 shown in FIG. 12.

FIG. 17 is a diagram for explaining the process of forming the organic layer OR1 and the upper electrode UE1 of the display element 201 shown in FIG. 11 by the evaporation device 100 shown in FIG. 12.

FIG. 18 is a diagram for explaining the process of forming the organic layer OR1 and the upper electrode UE1 of the display element 201 shown in FIG. 11 by the evaporation device 100 shown in FIG. 12.

FIG. 19 is a diagram for explaining another configuration example of the evaporation device 100.

FIG. 20 is a diagram for explaining the process of forming the organic layer OR1, the upper electrode UE1 and the cap layer CP1 of the display element 201 shown in FIG. 10 by the evaporation device 100 shown in FIG. 19.

FIG. 21 is a diagram for explaining the process of forming the organic layer OR1, the upper electrode UE1 and the cap layer CP1 of the display element 201 shown in FIG. 11 by the evaporation device 100 shown in FIG. 19.

FIG. 22 is a diagram for explaining the process of forming the organic layer OR1, the upper electrode UE1 and the cap layer CP1 of the display element 201 shown in FIG. 11 by the evaporation device 100 shown in FIG. 19.

### DETAILED DESCRIPTION

Embodiments described herein aim to provide an evaporation device and an evaporation method such that the cost and the installation space can be reduced.

In general, according to one embodiment, an evaporation device comprises a first chamber group comprising a plurality of evaporation chambers which are arranged in line in a first conveyance direction in which a processing substrate is conveyed, a second chamber group comprising a plurality of evaporation chambers which are arranged in line in a second conveyance direction which is an opposite direction of the first conveyance direction, a first rotation chamber which is connected to a first evaporation chamber located at a most upstream position in the first conveyance direction in the first chamber group and a second evaporation chamber located at a most downstream position in the second conveyance direction in the second chamber group and rotates the processing substrate carried out of the second evaporation chamber to carry the processing substrate into the first evaporation chamber, and a second rotation chamber which is connected to a third evaporation chamber located at a most downstream position in the first conveyance direction in the first chamber group and a fourth evaporation chamber located at a most upstream position in the second conveyance direction in the second chamber group and rotates the processing substrate carried out of the third evaporation chamber so as to carry the processing substrate into the fourth evaporation chamber.

According to another embodiment, an evaporation method comprises preparing a processing substrate by forming a lower electrode above a substrate, forming a rib comprising an aperture overlapping the lower electrode, and forming a partition including a lower portion located on the rib and an upper portion located on the lower portion and protruding from a side surface of the lower portion, and carrying the processing substrate in an evaporation device without providing a mask, forming an organic layer, forming an upper electrode on the organic layer, and carrying the processing substrate out of the evaporation device. In the evaporation device, the processing substrate which is carried in passes through a first rotation chamber, goes through a first chamber group comprising a plurality of evaporation chambers arranged in line in a first conveyance direction, is rotated 180° in a second rotation chamber, goes through a second chamber group comprising a plurality of evaporation chambers arranged in line in a second conveyance direction which is an opposite direction of the first conveyance direction, is rotated 180° in the first rotation chamber, goes through the first chamber group, is rotated 180° in the second rotation chamber, goes through the second chamber group, and passes through the first rotation chamber and is carried out of the evaporation device. In the processing substrate which is carried out of the evaporation device, the organic layer and the upper electrode formed on the partition are spaced apart from the organic layer and the upper electrode formed on the lower electrode in the aperture.

The embodiments can provide an evaporation device and an evaporation method such that the cost and the installation space can be reduced.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as a first direction. A direction parallel to the Y-axis is referred to as a second direction. A direction parallel to the Z-axis is referred to as a third direction. When various elements are viewed parallel to the third direction Z, the appearance is defined as a plan view. Here, the positive direction of the Z-axis is referred to as an upward direction or a direction to an upper side. When terms indicating the positional relationships of two or more structural elements, such as “on”, “above” and “face”, are used, the target structural elements may be in contact with each other or may be spaced apart from each other as a gap or another structural element is interposed between them.

The display device of the present embodiment is an organic electroluminescent display device comprising an organic light emitting diode (OLED) as a display element, and could be mounted on a television, a personal computer, a vehicle-mounted device, a tablet, a smartphone, a mobile phone, etc.

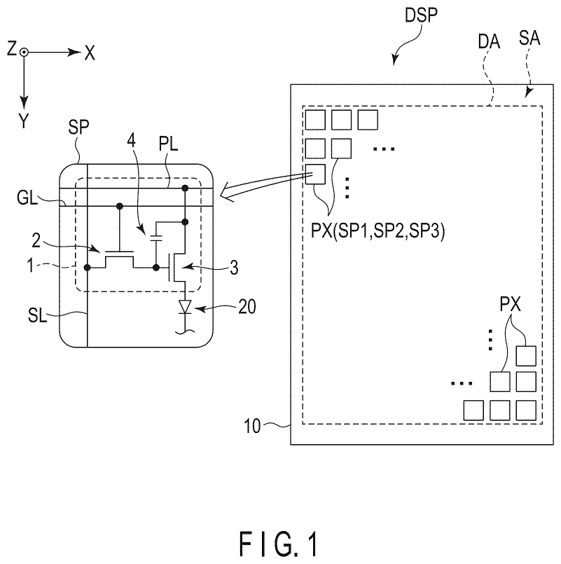

FIG. 1 is a diagram showing a configuration example of a display device DSP.

The display device DSP comprises a display area DA which displays an image and a surrounding area SA around the display area DA on an insulating substrate 10. The substrate 10 may be glass or a resinous film having flexibility.

In the present embodiment, the substrate 10 is rectangular as seen in plan view. It should be noted that the shape of the substrate 10 in plan view is not limited to a rectangular shape and may be another shape such as a square shape, a circular shape or an elliptic shape.

The display area DA comprises a plurality of pixels PX arrayed in matrix in a first direction X and a second direction Y. Each pixel PX includes a plurality of subpixels SP. For example, each pixel PX includes subpixel SP1 which exhibits a first color, subpixel SP2 which exhibits a second color and subpixel SP3 which exhibits a third color. The first color, the second color and the third color are different colors. Each pixel PX may include a subpixel SP which exhibits another color such as white in addition to subpixels SP1, SP2 and SP3 or instead of one of subpixels SP1, SP2 and SP3. It should be noted that the combination of subpixels is not limited to three elements. The combination may consist of two elements or may consist of four or more elements by adding subpixel SP4, etc., to subpixels SP1 to SP3.

Each subpixel SP comprises a pixel circuit 1 and a display element 20 driven by the pixel circuit 1. The pixel circuit 1 comprises a pixel switch 2, a drive transistor 3 and a capacitor 4. The pixel switch 2 and the drive transistor 3 are, for example, switching elements consisting of thin-film transistors.

The gate electrode of the pixel switch 2 is connected to a scanning line GL. One of the source electrode and drain electrode of the pixel switch 2 is connected to a signal line SL. The other one is connected to the gate electrode of the drive transistor 3 and the capacitor 4. In the drive transistor 3, one of the source electrode and the drain electrode is connected to a power line PL and the capacitor 4, and the other one is connected to the anode of the display element 20.

It should be noted that the configuration of the pixel circuit 1 is not limited to the example shown in the figure. For example, the pixel circuit 1 may comprise more thin-film transistors and capacitors.

The display element 20 is an organic light emitting diode (OLED) as a light emitting element, and may be called an organic EL element.

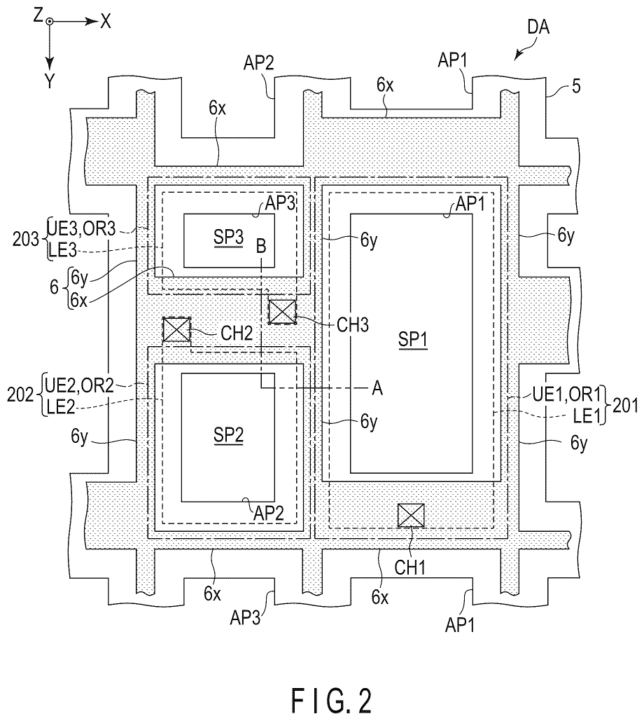

FIG. 2 is a diagram showing an example of the layout of subpixels SP1, SP2 and SP3.

In the example of FIG. 2, subpixels SP2 and SP3 are arranged in the second direction Y. Further, each of subpixels SP2 and SP3 is adjacent to subpixel SP1 in the first direction X.

When subpixels SP1, SP2 and SP3 are provided in line with this layout, in the display area DA, a column in which subpixels SP2 and SP3 are alternately provided in the second direction Y and a column in which a plurality of subpixels SP1 are repeatedly provided in the second direction Y are formed. These columns are alternately arranged in the first direction X.

It should be noted that the layout of subpixels SP1, SP2 and SP3 is not limited to the example of FIG. 2. As another example, subpixels SP1, SP2 and SP3 in each pixel PX may be arranged in order in the first direction X.

A rib 5 and a partition 6 are provided in the display area DA. The rib 5 comprises apertures AP1, AP2 and AP3 in subpixels SP1, SP2 and SP3, respectively.

The partition 6 overlaps the rib 5 as seen in plan view. The partition 6 comprises a plurality of first partitions 6x extending in the first direction X and a plurality of second partitions 6y extending in the second direction Y. The first partitions 6x are provided between the apertures AP2 and AP3 which are adjacent to each other in the second direction Y and between two apertures AP1 which are adjacent to each other in the second direction Y. Each second partition 6y is provided between the apertures AP1 and AP2 which are adjacent to each other in the first direction X and between the apertures AP1 and AP3 which are adjacent to each other in the first direction X.

In the example of FIG. 2, the first partitions 6x and the second partitions 6y are connected to each other. Thus, the partition 6 is formed into a grating shape surrounding the apertures AP1, AP2 and AP3 as a whole. In other words, the partition 6 comprises apertures in subpixels SP1, SP2 and SP3 in a manner similar to that of the rib 5.

Subpixels SP1, SP2 and SP3 comprise display elements 201, 202 and 203, respectively, as the display elements 20.

Subpixel SP1 comprises a lower electrode LE1, an upper electrode UE1 and an organic layer OR1 overlapping the aperture AP1. Subpixel SP2 comprises a lower electrode LE2, an upper electrode UE2 and an organic layer OR2 overlapping the aperture AP2. Subpixel SP3 comprises a lower electrode LE3, an upper electrode UE3 and an organic layer OR3 overlapping the aperture AP3.

In the example of FIG. 2, the outer shapes of the lower electrodes LE1, LE2 and LE3 are shown by dotted lines, and the outer shapes of the organic layers OR1, OR2 and OR3 and the upper electrodes UE1, UE2 and UE3 are shown by alternate long and short dash lines. The peripheral portion of each of the lower electrodes LE1, LE2 and LE3 overlaps the rib 5. It should be noted that the outer shape of each of the lower electrodes, organic layers and upper electrodes shown in the figure does not necessarily reflect the accurate shape.

The lower electrode LE1, the upper electrode UE1 and the organic layer OR1 constitute the display element 201 of subpixel SP1. The lower electrode LE2, the upper electrode UE2 and the organic layer OR2 constitute the display element 202 of subpixel SP2. The lower electrode LE3, the upper electrode UE3 and the organic layer OR3 constitute the display element 203 of subpixel SP3.

The lower electrodes LE1, LE2 and LE3 correspond to, for example, the anodes of the display elements. The upper electrodes UE1, UE2 and UE3 correspond to the cathodes of the display elements or a common electrode.

The lower electrode LE1 is connected to the pixel circuit 1 (see FIG. 1) of subpixel SP1 through a contact hole CH1. The lower electrode LE2 is connected to the pixel circuit 1 of subpixel SP2 through a contact hole CH2. The lower electrode LE3 is connected to the pixel circuit 1 of subpixel SP3 through a contact hole CH3.

In the example of FIG. 2, the area of the aperture AP1 is greater than that of the aperture AP2, and the area of the aperture AP2 is greater than that of the aperture AP3. In other words, the area of the lower electrode LE1 exposed from the aperture AP1 is greater than that of the lower electrode LE2 exposed from the aperture AP2. The area of the lower electrode LE2 exposed from the aperture AP2 is greater than that of the lower electrode LE3 exposed from the aperture AP3.

For example, the display element 201 of subpixel SP1 is configured to emit light in a blue wavelength range. The display element 202 of subpixel SP2 is configured to emit light in a green wavelength range. The display element 203 of subpixel SP3 is configured to emit light in a red wavelength range.

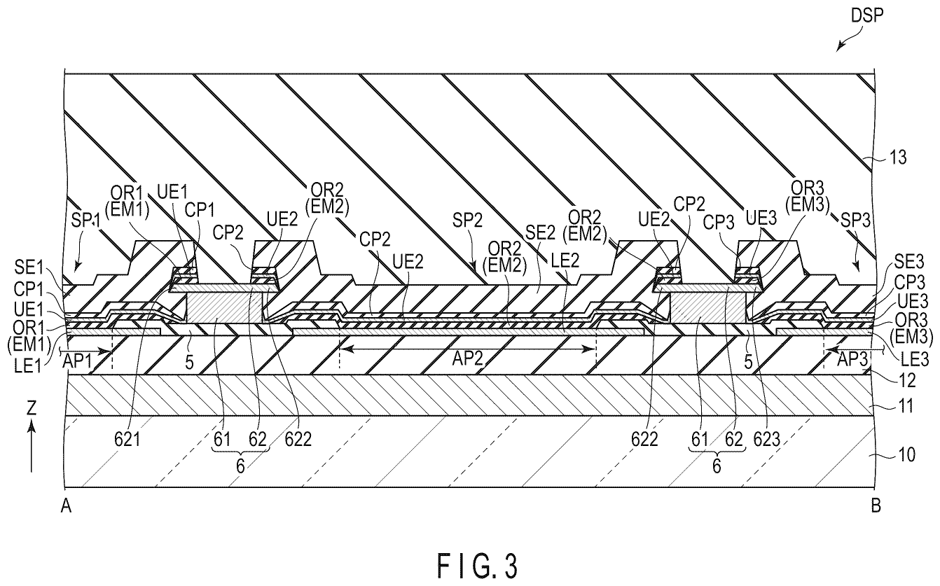

FIG. 3 is a schematic cross-sectional view of the display device DSP along the A-B line of FIG. 2.

A circuit layer 11 is provided on the substrate 10 described above. The circuit layer 11 includes various circuits and lines such as the pixel circuit 1, scanning line GL, signal line SL and power line PL shown in FIG. 1. The circuit layer 11 is covered with an insulating layer 12. The insulating layer 12 functions as a planarization film which planarizes the irregularities formed by the circuit layer 11.

The lower electrodes LE1, LE2 and LE3 are provided on the insulating layer 12. The rib 5 is provided on the insulating layer 12 and the lower electrodes LE1, LE2 and LE3. The end portions of the lower electrodes LE1, LE2 and LE3 are covered with the rib 5. In other words, the end portions of the lower electrodes LE1, LE2 and LE3 are provided between the insulating layer 12 and the rib 5. Of the lower electrodes LE1, LE2 and LE3, between the lower electrodes which are adjacent to each other, the insulating layer 12 is covered with the rib 5.

The partition 6 includes a lower portion (stem) 61 provided on the rib 5 and an upper portion (hat) 62 provided on the lower portion 61. The lower portion 61 of the partition 6 shown on the left side of the figure is located between the aperture AP1 and the aperture AP2. The lower portion 61 of the partition 6 shown on the right side of the figure is located between the aperture AP2 and the aperture AP3. The upper portion 62 has a width greater than that of the lower portion 61. By this configuration, the both end portions of the upper portion 62 protrude relative to the side surfaces of the lower portion 61. This shape of the partition 6 may be called an overhang shape. Of the upper portion 62, a portion which protrudes to the aperture AP1 relative to the lower portion 61 is referred to as a protrusion 621. A portion which protrudes to the aperture AP2 relative to the lower portion 61 is referred to as a protrusion 622. A portion which protrudes to the aperture AP3 relative to the lower portion 61 is referred to as a protrusion 623.

The organic layer OR1 is in contact with the lower electrode LE1 through the aperture AP1, covers the lower electrode LE1 and overlaps part of the rib 5. The upper electrode UE1 faces the lower electrode LE1 and is provided on the organic layer OR1. Further, the upper electrode UE1 is in contact with a side surface of the lower portion 61. The organic layer OR1 and the upper electrode UE1 are located on the lower side relative to the upper portion 62.

The organic layer OR2 is in contact with the lower electrode LE2 through the aperture AP2, covers the lower electrode LE2 and overlaps part of the rib 5. The upper electrode UE2 faces the lower electrode LE2 and is provided on the organic layer OR2. Further, the upper electrode UE2 is in contact with a side surface of the lower portion 61. The organic layer OR2 and the upper electrode UE2 are located on the lower side relative to the upper portion 62.

The organic layer OR3 is in contact with the lower electrode LE3 through the aperture AP3, covers the lower electrode LE3 and overlaps part of the rib 5. The upper electrode UE3 faces the lower electrode LE3 and is provided on the organic layer OR3. Further, the upper electrode UE3 is in contact with a side surface of the lower portion 61. The organic layer OR3 and the upper electrode UE3 are located on the lower side relative to the upper portion 62.

In the example shown in the figure, subpixels SP1, SP2 and SP3 include cap layers (optical adjustment layers) CP1, CP2 and CP3 for adjusting the optical property of the light emitted from the light emitting layers of the organic layers OR1, OR2 and OR3. It should be noted that at least one of the cap layers CP1 to CP3 may be omitted.

The cap layer CP1 is located in the aperture AP1, is located on the lower side relative to the upper portion 62 and is provided on the upper electrode UE1. The cap layer CP2 is located in the aperture AP2, is located on the lower side relative to the upper portion 62 and is provided on the upper electrode UE2. The cap layer CP3 is located in the aperture AP3, is located on the lower side relative to the upper portion 62 and is provided on the upper electrode UE3.

Sealing layers SE1, SE2 and SE3 are provided in subpixels SP1, SP2 and SP3, respectively.

The sealing layer SE1 is in contact with the cap layer CP1 and the lower and upper portions 61 and 62 of the partition 6 and continuously covers the members of subpixel SP1. The sealing layer SE1 does not comprise a void under the protrusion 621 of the partition 6.

The sealing layer SE2 is in contact with the cap layer CP2 and the lower and upper portions 61 and 62 of the partition 6 and continuously covers the members of subpixel SP2. The sealing layer SE2 does not comprise a void under the protrusion 622 of the partition 6.

The sealing layer SE3 is in contact with the cap layer CP3 and the lower and upper portions 61 and 62 of the partition 6 and continuously covers the members of subpixel SP3. The sealing layer SE3 does not comprise a void under the protrusion 623 of the partition 6.

The sealing layers SE1, SE2 and SE3 are covered with a protective layer 13.

In the example shown in the figure, part of the organic layer OR1, part of the upper electrode UE1 and part of the cap layer CP1 are located between the partition 6 and the sealing layer SE1, are provided on the upper portion 62 and are spaced apart from the portions located on the lower side relative to the upper portion 62.

Part of the organic layer OR2, part of the upper electrode UE2 and part of the cap layer CP2 are located between the partition 6 and the sealing layer SE2, are provided on the upper portion 62 and are spaced apart from the portions located on the lower side relative to the upper portion 62.

Part of the organic layer OR3, part of the upper electrode UE3 and part of the cap layer CP3 are located between the partition 6 and the sealing layer SE3, are provided on the upper portion 62 and are spaced apart from the portions located on the lower side relative to the upper portion 62.

The insulating layer 12 is an organic insulating layer. The rib 5 and the sealing layers SE1, SE2 and SE3 are inorganic insulating layers.

The rib 5 is formed of silicon nitride (SiNx) as an example of inorganic insulating materials. It should be noted that the rib 5 may be formed as, as another inorganic insulating material, a single-layer body of one of silicon oxide (SiOx), silicon oxynitride (SiON) and aluminum oxide (Al₂O₃). The rib 5 may be formed as a stacked layer body of a combination consisting of at least two of a silicon nitride layer, a silicon oxide layer, a silicon oxynitride layer and an aluminum oxide layer.

The sealing layers SE1, SE2 and SE3 are formed of, for example, the same inorganic insulating material.

The sealing layers SE1, SE2 and SE3 are formed of silicon nitride (SiNx) as an example of inorganic insulating materials. It should be noted that each of the sealing layers SE1, SE2 and SE3 may be formed as, as another inorganic insulating material, a single-layer body of one of silicon oxide (SiOx), silicon oxynitride (SiON) and aluminum oxide (Al₂O₃). Each of the sealing layers SE1, SE2 and SE3 may be formed as a stacked layer body of a combination consisting of at least two of a silicon nitride layer, a silicon oxide layer, a silicon oxynitride layer and an aluminum oxide layer. Thus, the sealing layers SE1, SE2 and SE3 may be formed of the same material as the rib 5.

The lower portion 61 of the partition 6 is formed of a conductive material and is electrically connected to the upper electrodes UE1, UE2 and UE3. Both the lower portion 61 and the upper portion 62 of the partition 6 may be formed of a conductive material.

The thickness of the rib 5 is sufficiently less than the thicknesses of the partition 6 and the insulating layer 12. For example, the thickness of the rib 5 is greater than or equal to 200 nm but less than or equal to 400 nm.

The thickness of the lower portion 61 of the partition 6 (the thickness from the upper surface of the rib 5 to the lower surface of the upper portion 62) is greater than that of the rib 5.

The thickness of the sealing layer SE1, the thickness of the sealing layer SE2 and the thickness of the sealing layer SE3 are substantially equal to each other and are, for example, approximately 1 μm.

Each of the lower electrodes LE1, LE2 and LE3 may be formed of a transparent conductive material such as ITO or may comprise a multilayer structure of a metal material such as silver (Ag) and a transparent conductive material. Each of the upper electrodes UE1, UE2 and UE3 is formed of, for example, a metal material such as an alloy of magnesium and silver (MgAg). Each of the upper electrodes UE1, UE2 and UE3 may be formed of a transparent conductive material such as ITO.

Each of the organic layers OR1, OR2 and OR3 includes a plurality of functional layers such as a hole injection layer, a hole transport layer, an electron blocking layer, a hole blocking layer, an electron transport layer and an electron injection layer. The organic layer OR1 includes a light emitting layer EM1. The organic layer OR2 includes a light emitting layer EM2. The light emitting layer EM2 is formed of a material different from that of the light emitting layer EM1. The organic layer OR3 includes a light emitting layer EM3. The light emitting layer EM3 is formed of a material different from the materials of the light emitting layers EM1 and EM2.

The material of the light emitting layer EM1, the material of the light emitting layer EM2 and the material of the light emitting layer EM3 are materials which emit light in different wavelength ranges.

For example, the light emitting layer EM1 is formed of a material which emits light in a blue wavelength range. The light emitting layer EM2 is formed of a material which emits light in a green wavelength range. The light emitting layer EM3 is formed of a material which emits light in a red wavelength range.

Each of the cap layers CP1, CP2 and CP3 is formed of, for example, a multilayer body consisting of transparent thin films. As the thin films, the multilayer body may include a thin film formed of an inorganic material and a thin film formed of an organic material. These thin films have refractive indices different from each other. The materials of the thin films constituting the multilayer body are different from the materials of the upper electrodes UE1, UE2 and UE3 and are also different from the materials of the sealing layers SE1, SE2 and SE3. It should be noted that the cap layers CP1, CP2 and CP3 may be omitted.

The protective layer 13 is formed of a multilayer body consisting of transparent thin films. For example, as the thin films, the multilayer body includes a thin film formed of an inorganic material and a thin film formed of an organic material. Common voltage is applied to the partition 6.

This common voltage is applied to each of the upper electrodes UE1, UE2 and UE3 which are in contact with the side surfaces of the lower portions 61. Pixel voltage is applied to the lower electrodes LE1, LE2 and LE3 through the pixel circuits 1 provided in subpixels SP1, SP2 and SP3, respectively.

When a potential difference is formed between the lower electrode LE1 and the upper electrode UE1, the light emitting layer EM1 of the organic layer OR1 emits light in a blue wavelength range. When a potential difference is formed between the lower electrode LE2 and the upper electrode UE2, the light emitting layer EM2 of the organic layer OR2 emits light in a green wavelength range. When a potential difference is formed between the lower electrode LE3 and the upper electrode UE3, the light emitting layer EM3 of the organic layer OR3 emits light in a red wavelength range.

Now, this specification explains an example of the manufacturing method of the display device DSP.

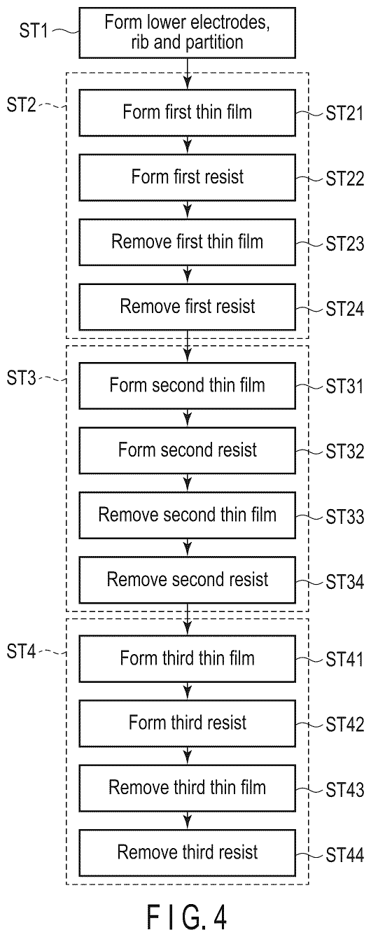

FIG. 4 is a flow diagram for explaining an example of the manufacturing method of the display device DSP.

The manufacturing method shown here roughly includes the process of preparing a processing substrate SUB comprising subpixels SP1, SP2 and SP3 (step ST1), the process of forming the display element 201 of subpixel SP1 (step ST2), the process of forming the display element 202 of subpixel SP2 (step ST3) and the process of forming the display element 203 of subpixel SP3 (step ST4).

In step ST1, first, the processing substrate SUB is prepared by forming the lower electrode LE1 of subpixel SP1, the lower electrode LE2 of subpixel SP2, the lower electrode LE3 of subpixel SP3, the rib 5 and the partition 6 on the substrate 10. As shown in FIG. 3, the circuit layer 11 and the insulating layer 12 are also formed between the substrate 10 and the lower electrodes LE1, LE2 and LE3.

In step ST2, first, a first thin film 31 including the light emitting layer EM1 is formed over subpixel SP1, subpixel SP2 and subpixel SP3 (step ST21). The first thin film 31 is a stacked layer body of the organic layer OR1, upper electrode UE1, cap layer CP1 and sealing layer SE1 shown in FIG. 3. Subsequently, a first resist 41 patterned into a predetermined shape is formed on the first thin film 31 (step ST22). Subsequently, part of the first thin film 31 is removed by etching using the first resist 41 as a mask (step ST23). At this time, for example, the first thin film 31 provided in subpixel SP2 and subpixel SP3 is removed. Subsequently, the first resist 41 is removed (step ST24). In this way, subpixel SP1 is formed. Subpixel SP1 comprises the display element 201 comprising the first thin film 31 having a predetermined shape.

In step ST3, first, a second thin film 32 including the light emitting layer EM2 is formed over subpixel SP1, subpixel SP2 and subpixel SP3 (step ST31). The second thin film 32 is a stacked layer body of the organic layer OR2, upper electrode UE2, cap layer CP2 and sealing layer SE2 shown in FIG. 3. Subsequently, a second resist 42 patterned into a predetermined shape is formed on the second thin film 32 (step ST32). Subsequently, part of the second thin film 32 is removed by etching using the second resist 42 as a mask (step ST33). At this time, for example, the second thin film 32 provided in subpixel SP1 and subpixel SP3 is removed. Subsequently, the second resist 42 is removed (step ST34). In this way, subpixel SP2 is formed. Subpixel SP2 comprises the display element 202 comprising the second thin film 32 having a predetermined shape.

In step ST4, first, a third thin film 33 including the light emitting layer EM3 is formed over subpixel SP1, subpixel SP2 and subpixel SP3 (step ST41). The third thin film 33 is a stacked layer body of the organic layer OR3, upper electrode UE3, cap layer CP3 and sealing layer SE3 shown in FIG. 3. Subsequently, a third resist 43 patterned into a predetermined shape is formed on the third thin film 33 (step ST42). Subsequently, part of the third thin film 33 is removed by etching using the third resist 43 as a mask (step ST43). At this time, for example, the third thin film 33 provided in subpixel SP1 and subpixel SP2 is removed. Subsequently, the third resist 43 is removed (step ST44). In this way, subpixel SP3 is formed. Subpixel SP3 comprises the display element 203 comprising the third thin film 33 having a predetermined shape.

It should be noted that the detailed illustrations of the second thin film 32, the second resist 42, the third thin film 33 and the third resist 43 are omitted.

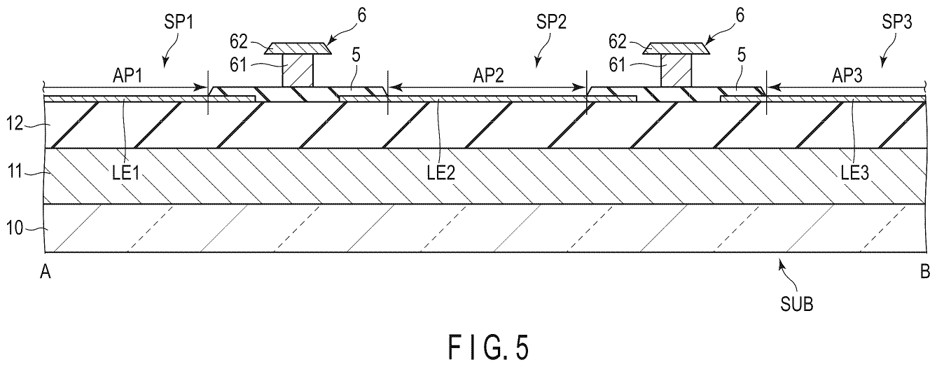

Now, this specification explains step ST1 and step ST2 with reference to FIG. 5 to FIG. 9. The section shown in each of FIG. 5 to FIG. 9 corresponds to, for example, the section taken along the A-B line of FIG. 2.

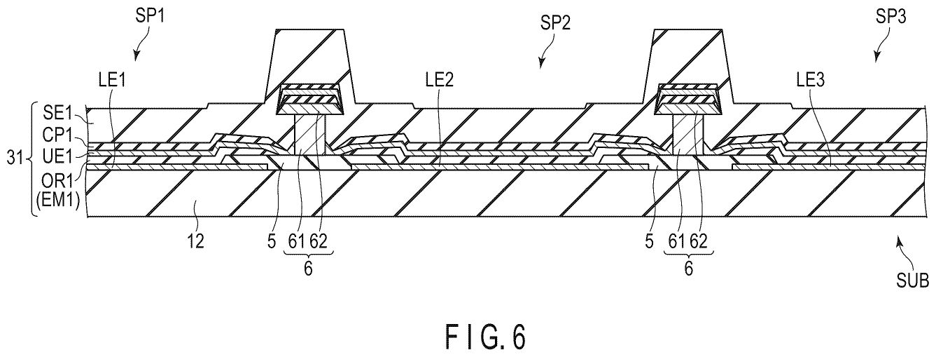

First, in step ST1, as shown in FIG. 5, the processing substrate SUB is prepared. The process of preparing the processing substrate SUB includes the process of forming the circuit layer 11 on the substrate 10, the process of forming the insulating layer 12 on the circuit layer 11, the process of forming the lower electrode LE1 of subpixel SP1, the lower electrode LE2 of subpixel SP2 and the lower electrode LE3 of subpixel SP3 on the insulating layer 12, the process of forming the rib 5 comprising the apertures AP1, AP2 and AP3 overlapping the lower electrodes LE1, LE2 and LE3, respectively, and the process of forming the partition 6 including the lower portion 61 provided on the rib 5 and the upper portion 62 provided on the lower portion 61 and protruding from the side surfaces of the lower portion 61. The rib 5 is formed of, for example, silicon nitride. Of the partition 6, at least the lower portion 61 is formed of a conductive material. In each of FIG. 6 to FIG. 9, the illustrations of the substrate 10 and the circuit layer 11 lower than the insulating layer 12 are omitted.

Subsequently, in step ST21, as shown FIG. 6, the first thin film 31 is formed over subpixel SP1, subpixel SP2 and subpixel SP3. The process of forming the first thin film 31 includes, on the processing substrate SUB, the process of forming the organic layer OR1 including the light emitting layer EM1, the process of forming the upper electrode UE1 on the organic layer OR1, the process of forming the cap layer CP1 on the upper electrode UE1 and the process of forming the sealing layer SE1 on the cap layer CP1. Thus, in the example shown in the figure, the first thin film 31 includes the organic layer OR1, the upper electrode UE1, the cap layer CP1 and the sealing layer SE1.

The organic layer OR1 is formed on each of the lower electrode LE1, the lower electrode LE2 and the lower electrode LE3 and is also formed on the partition 6. Of the organic layer OR1, the portion formed on each upper portion 62 is spaced apart from the portion formed on each of the lower electrodes. The various functional layers and the light emitting layer EM1 of the organic layer OR1 are formed by a vapor deposition method.

The upper electrode UE1 is formed on the organic layer OR1 immediately above each of the lower electrodes LE1, LE2 and LE3, covers the rib 5 and is in contact with the lower portion 61 of the partition 6. The upper electrode UE1 is also formed on the organic layer OR1 immediately above each upper portion 62. Of the upper electrode UE1, the portion which is formed immediately above each upper portion 62 is spaced apart from the portion which is formed immediately above each of the lower electrodes. The upper electrode UE1 is formed by a vapor deposition method.

The cap layer CP1 is formed on the upper electrode UE1 immediately above each of the lower electrode LE1, the lower electrode LE2 and the lower electrode LE3, and is also formed on the upper electrode UE1 immediately above each upper portion 62. Of the cap layer CP1, the portion which is formed immediately above each upper portion 62 is spaced apart from the portion which is formed immediately above each of the lower electrodes. The first and second transparent layers included in the cap layer CP1 are formed by a vapor deposition method.

The sealing layer SE1 is formed so as to cover the cap layer CP1 and the partition 6. In other words, the sealing layer SE1 is formed on the cap layer CP1 immediately above each of the lower electrode LE1, the lower electrode LE2 and the lower electrode LE3, and is also formed on the cap layer CP1 immediately above each upper portion 62. In the sealing layer SE1, the portion which is formed immediately above each upper portion 62 is continuous with the portion which is formed immediately above each of the lower electrodes. The sealing layer SE1 is formed by a CVD method. The upper electrode UE1 is interposed between the rib 5 and the sealing layer SE1. The sealing layer SE1 is spaced apart from the rib 5.

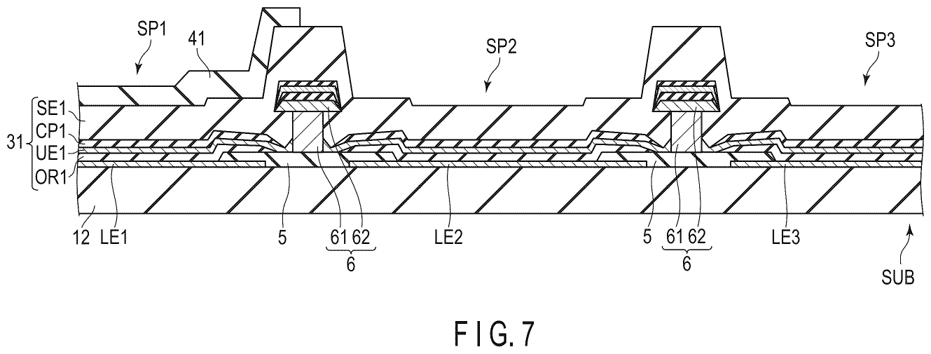

Subsequently, in step ST22, as shown in FIG. 7, the patterned first resist 41 is formed on the sealing layer SE1. The first resist 41 covers the first thin film 31 of subpixel SP1, and the first thin film 31 is exposed from the first resist 41 in subpixels SP2 and SP3. Thus, the first resist 41 overlaps the sealing layer SE1 located immediately above the lower electrode LE1. The first resist 41 extends from subpixel SP1 to the upper side of the partition 6. On the partition 6 between subpixel SP1 and subpixel SP2, the first resist 41 is provided on the subpixel SP1 side (the left side of the figure), and the sealing layer SE1 is exposed from the first resist 41 on the subpixel SP2 side (the right side of the figure). The sealing layer SE1 is exposed from the first resist 41 in subpixel SP2 and subpixel SP3.

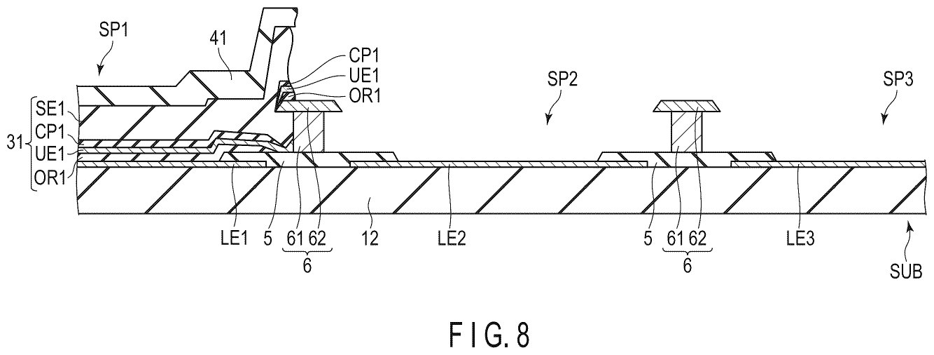

Subsequently, in step ST23, as shown in FIG. 8, etching is applied using the first resist 41 as a mask. By this process, the first thin film 31 exposed from the first resist 41 in subpixels SP2 and SP3 is removed, and the first thin film 31 remains in subpixel SP1.

The process of removing the first thin film 31 is, for example, as follows.

First, dry etching is performed using the first resist 41 as a mask to remove the sealing layer SE1 exposed from the first resist 41.

Subsequently, wet etching is performed using the first resist 41 as a mask to remove the second transparent layer of the cap layer CP1 exposed from the sealing layer SE1.

Subsequently, dry etching is performed using the first resist 41 as a mask to remove the first transparent layer of the cap layer CP1 exposed from the second transparent layer.

Subsequently, wet etching is performed using the first resist 41 as a mask to remove the upper electrode UE1 exposed from the first transparent layer.

Subsequently, dry etching is performed using the first resist 41 as a mask to remove the organic layer OR1 exposed from the upper electrode UE1.

In this way, the lower electrode LE2 is exposed in subpixel SP2, and the rib 5 surrounding the lower electrode LE2 is exposed. In subpixel SP3, the lower electrode LE3 is exposed, and the rib 5 surrounding the lower electrode LE3 is exposed. On the partition 6 between subpixel SP1 and subpixel SP2, the subpixel SP2 side is exposed. Further, the partition 6 between subpixel SP2 and subpixel SP3 is exposed.

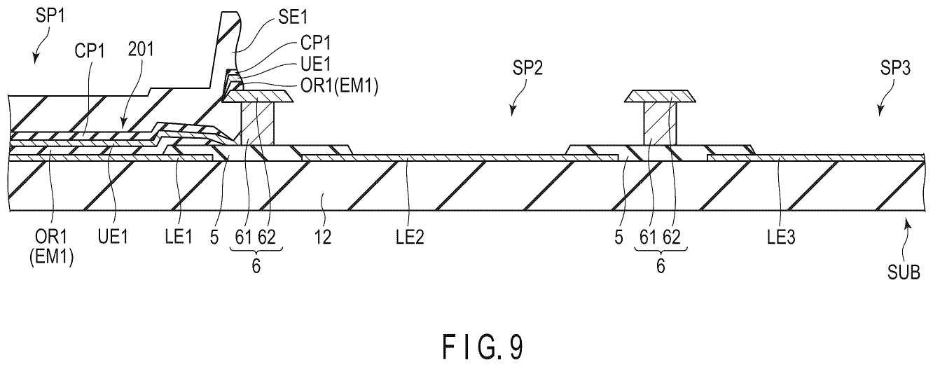

Subsequently, in step ST24, as shown in FIG. 9, the first resist 41 is removed. Thus, the sealing layer SE1 of subpixel SP1 is exposed. Through these steps ST21 to ST24, the display element 201 is formed in subpixel SP1. The display element 201 consists of the lower electrode LE1, the organic layer OR1 including the light emitting layer EM1, the upper electrode UE1 and the cap layer CP1. The display element 201 is covered with the sealing layer SE1.

A stacked layer body of the organic layer OR1 including the light emitting layer EM1, the upper electrode UE1, the cap layer CP1 and the sealing layer SE1 is formed on the partition 6 between subpixel SP1 and subpixel SP2. Of the partition 6, the portion on the subpixel SP1 side is covered with the sealing layer SE1. It should be noted that the stacked layer body on the partition 6 shown in FIG. 9 is completely eliminated in some cases.

Steps ST31 to ST34 shown in FIG. 4 are similar to steps ST21 to ST24 described above. Through these steps ST31 to ST34, the display element 202 is formed in subpixel SP2 shown in FIG. 3. The display element 202 consists of the lower electrode LE2, the organic layer OR2 including the light emitting layer EM2, the upper electrode UE2 and the cap layer CP2. The display element 202 is covered with the sealing layer SE2.

Steps ST41 to ST44 shown in FIG. 4 are also similar to steps ST21 to ST24 described above. Through these steps ST41 to ST44, the display element 203 is formed in subpixel SP3 shown in FIG. 3. The display element 203 consists of the lower electrode LE3, the organic layer OR3 including the light emitting layer EM3, the upper electrode UE3 and the cap layer CP3. The display element 203 is covered with the sealing layer SE3.

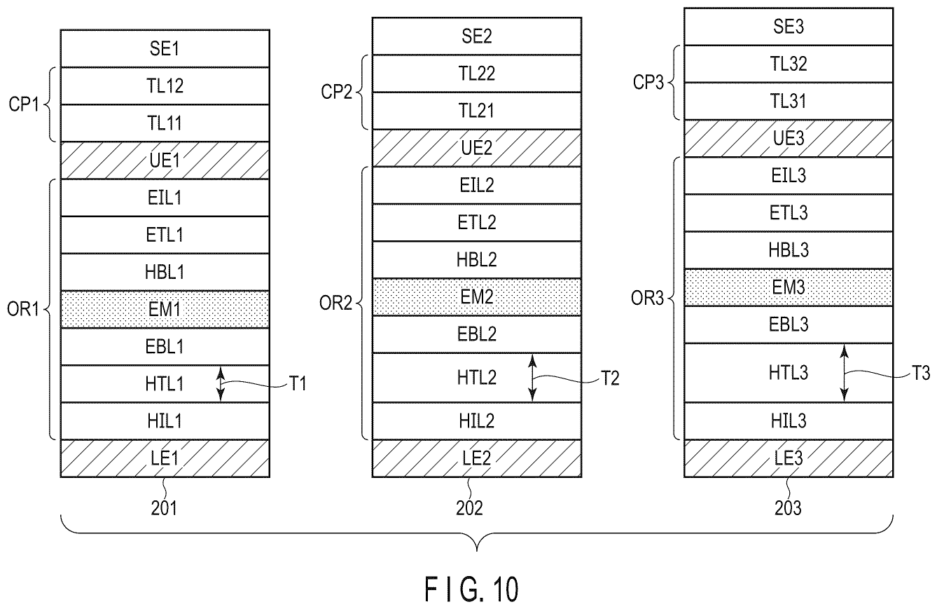

FIG. 10 is a diagram showing an example of the configuration of the display elements 201 to 203.

Here, in the example, this specification assumes that each lower electrode corresponds to an anode and each upper electrode corresponds to a cathode.

The display element 201 includes the organic layer OR1 between the lower electrode LE1 and the upper electrode UE1.

In the organic layer OR1, a hole injection layer HIL1, a hole transport layer HTL1, an electron blocking layer EBL1, the light emitting layer EM1, a hole blocking layer HBL1, an electron transport layer ETL1 and an electron injection layer EIL1 are stacked in this order.

The cap layer CP1 includes the first transparent layer TL11 and the second transparent layer TL12. The first transparent layer TL11 is provided on the upper electrode UE1. The second transparent layer TL12 is provided on the first transparent layer TL11. The sealing layer SE1 is provided on the second transparent layer TL12.

The display element 202 includes the organic layer OR2 between the lower electrode LE2 and the upper electrode UE2.

In the organic layer OR2, a hole injection layer HIL2, a hole transport layer HTL2, an electron blocking layer EBL2, the light emitting layer EM2, a hole blocking layer HBL2, an electron transport layer ETL2 and an electron injection layer EIL2 are stacked in this order. For example, thickness T2 of the hole transport layer HTL2 is greater than thickness T1 of the hole transport layer HTL1.

The cap layer CP2 includes a first transparent layer TL21 and a second transparent layer TL22. The first transparent layer TL21 is provided on the upper electrode UE2. The second transparent layer TL22 is provided on the first transparent layer TL21. The sealing layer SE2 is provided on the second transparent layer TL22.

The display element 203 includes the organic layer OR3 between the lower electrode LE3 and the upper electrode UE3.

In the organic layer OR3, a hole injection layer HIL3, a hole transport layer HTL3, an electron blocking layer EBL3, the light emitting layer EM3, a hole blocking layer HBL3, an electron transport layer ETL3 and an electron injection layer EIL3 are stacked in this order. For example, thickness T3 of the hole transport layer HTL3 is greater than thickness T2 of the hole transport layer HTL2.

The cap layer CP3 includes a first transparent layer TL31 and a second transparent layer TL32. The first transparent layer TL31 is provided on the upper electrode UE3. The second transparent layer TL32 is provided on the first transparent layer TL31. The sealing layer SE3 is provided on the second transparent layer TL32.

The first transparent layers TL11, TL21 and TL31 are, for example, organic layers each formed of an organic material, and are high refractive layers having refractive indices greater than those of the upper electrodes UE1, UE2 and UE3.

The second transparent layers TL12, TL22 and TL32 are, for example, inorganic layers each formed of an inorganic material such as lithium fluoride (LiF), and are low refractive layers having refractive indices less than those of the first transparent layers TL11, TL21 and TL31.

It should be noted that each of the cap layers CP1, CP2 and CP3 may be formed of a stacked layer body consisting of three or more layers.

In this specification, the configuration of the display elements 201 to 203 shown in FIG. 10 is called a single configuration.

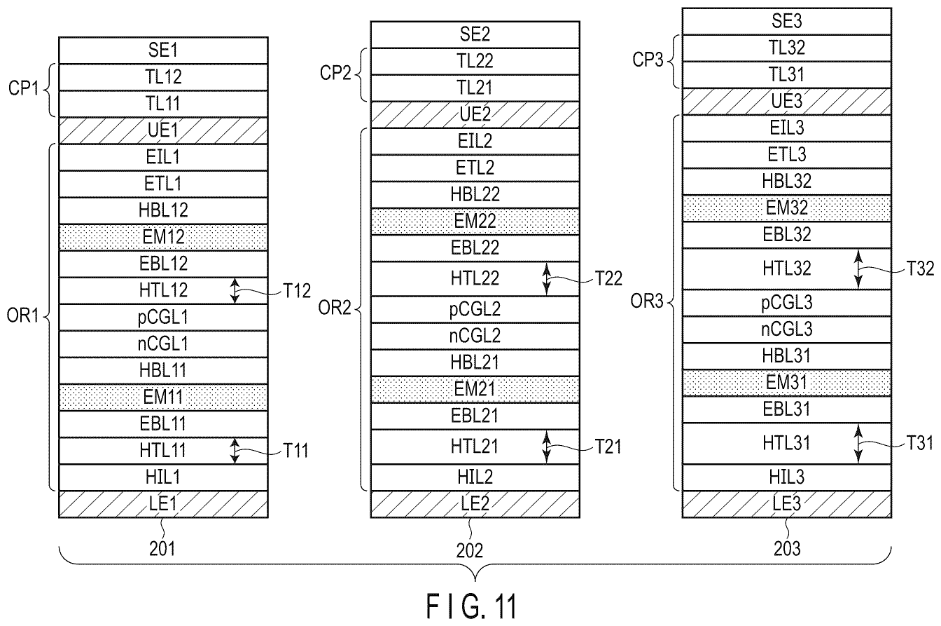

FIG. 11 is a diagram showing another example of the configuration of the display elements 201 to 203.

Here, in the example, this specification assumes that each lower electrode corresponds to an anode and each upper electrode corresponds to a cathode.

The display element 201 includes the organic layer OR1 between the lower electrode LE1 and the upper electrode UE1.

In the organic layer OR1, the hole injection layer HIL1, a hole transport layer HTL11, an electron blocking layer EBL11, a light emitting layer EM11, a hole blocking layer HBL11, an n-type charge generation layer nCGL1, a p-type charge generation layer pCGL1, a hole transport layer HTL12, an electron blocking layer EBL12, a light emitting layer EM12, a hole blocking layer HBL12, the electron transport layer ETL1 and the electron injection layer EIL1 are stacked in this order.

The hole transport layers HTL11 and HTL12 are formed of the same material.

The electron blocking layers EBL11 and EBL12 are formed of the same material.

The light emitting layers EM11 and EM12 are formed of the same material.

The hole blocking layers HBL11 and HBL12 are formed of the same material.

The n-type charge generation layer nCGL1 is a functional layer which supplies electrons to the light emitting layer EM11.

The p-type charge generation layer pCGL1 is a functional layer which supplies positive holes to the light emitting layer EM12.

The cap layer CP1 including the first transparent layer TL11 and the second transparent layer TL12 is provided on the upper electrode UE1. The sealing layer SE1 is provided on the second transparent layer TL12.

The display element 202 includes the organic layer OR2 between the lower electrode LE2 and the upper electrode UE2.

In the organic layer OR2, the hole injection layer HIL2, a hole transport layer HTL21, an electron blocking layer EBL21, a light emitting layer EM21, a hole blocking layer HBL21, an n-type charge generation layer nCGL2, a p-type charge generation layer pCGL2, a hole transport layer HTL22, an electron blocking layer EBL22, a light emitting layer EM22, a hole blocking layer HBL22, the electron transport layer ETL2 and the electron injection layer EIL2 are stacked in this order.

The hole transport layers HTL21 and HTL22 are formed of the same material. For example, thickness T21 of the hole transport layer HTL21 is greater than thickness T11 of the hole transport layer HTL11. Thickness T22 of the hole transport layer HTL22 is greater than thickness T12 of the hole transport layer HTL12.

The electron blocking layers EBL21 and EBL22 are formed of the same material.

The light emitting layers EM21 and EM22 are formed of the same material. The material of the light emitting layers EM21 and EM22 is different from that of the light emitting layers EM11 and EM12.

The hole blocking layers HBL21 and HBL22 are formed of the same material.

The n-type charge generation layer nCGL2 is a functional layer which supplies electrons to the light emitting layer EM21.

The p-type charge generation layer pCGL2 is a functional layer which supplies positive holes to the light emitting layer EM22.

The cap layer CP2 including the first transparent layer TL21 and the second transparent layer TL22 is provided on the upper electrode UE2. The sealing layer SE2 is provided on the second transparent layer TL22.

The display element 203 includes the organic layer OR3 between the lower electrode LE3 and the upper electrode UE3.

In the organic layer OR3, the hole injection layer HIL3, a hole transport layer HTL31, an electron blocking layer EBL31, a light emitting layer EM31, a hole blocking layer HBL31, an n-type charge generation layer nCGL3, a p-type charge generation layer pCGL3, a hole transport layer HTL32, an electron blocking layer EBL32, a light emitting layer EM32, a hole blocking layer HBL32, the electron transport layer ETL3 and the electron injection layer EIL3 are stacked in this order.

The hole transport layers HTL31 and HTL32 are formed of the same material. For example, thickness T31 of the hole transport layer HTL31 is greater than thickness T21 of the hole transport layer HTL21. Thickness T32 of the hole transport layer HTL32 is greater than thickness T22 of the hole transport layer HTL22.

The electron blocking layers EBL31 and EBL32 are formed of the same material.

The light emitting layers EM31 and EM32 are formed of the same material. The material of the light emitting layers EM31 and EM32 is different from that of the light emitting layers EM11 and EM12 and is different from that of the light emitting layers EM21 and EM22.

The hole blocking layers HBL31 and HBL32 are formed of the same material.

The n-type charge generation layer nCGL3 is a functional layer which supplies electrons to the light emitting layer EM31.

The p-type charge generation layer pCGL3 is a functional layer which supplies positive holes to the light emitting layer EM32.

The cap layer CP3 including the first transparent layer TL31 and the second transparent layer TL32 is provided on the upper electrode UE3. The sealing layer SE3 is provided on the second transparent layer TL32.

In this specification, the configuration of the display elements 201 to 203 shown in FIG. 11 is called a tandem configuration.

Now, this specification explains an evaporation device for forming the organic layer and the upper electrode of a display element. Here, for example, this specification explains an evaporation device 100 for forming the organic layer OR1 and the upper electrode UE1 of the display element 201. It should be noted that an evaporation device for forming the organic layer OR2 and the upper electrode UE2 of the display element 202 and an evaporation device for forming the organic layer OR3 and the upper electrode UE3 of the display element 203 can be configured in the same manner as the evaporation device 100 explained here.

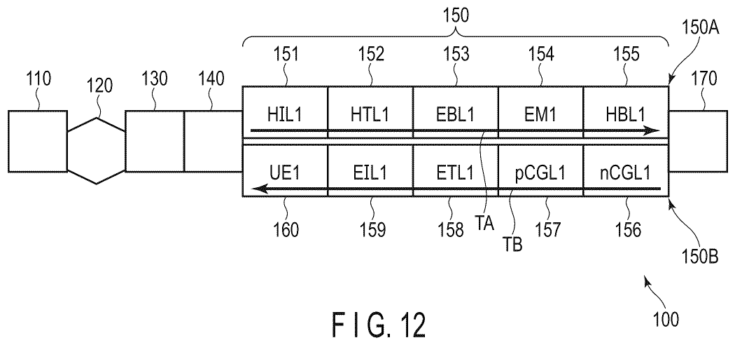

FIG. 12 is a diagram for explaining a configuration example of the evaporation device 100. The evaporation device 100 is applied to the formation of the organic layer OR1 and the upper electrode UE1 in the process of forming the first thin film 31 explained with reference to FIG. 4 and FIG. 6.

The evaporation device 100 comprises a load lock chamber 110, a conveyance chamber 120, a substrate attachment/detachment chamber 130, a first rotation chamber 140, an evaporation portion 150 and a second rotation chamber 170.

In the load lock chamber 110, for example, after the processing substrate SUB explained with reference to FIG. 5 is put in the chamber, the pressure is reduced using a vacuum pump. In the conveyance chamber 120, the substrate attachment/detachment chamber 130, the first rotation chamber 140, the evaporation portion 150 and the second rotation chamber 170, a predetermined reduced-pressure state is maintained.

The conveyance chamber 120 is connected to the load lock chamber 110. As described later, the conveyance chamber 120 comprises a substrate conveyance robot which conveys the processing substrate SUB put in the load lock chamber 110 to the substrate attachment/detachment chamber 130.

The substrate attachment/detachment chamber 130 is connected to the first rotation chamber 140. As described later, the substrate attachment/detachment chamber 130 comprises a mechanism for attaching the processing substrate SUB carried in the chamber to a dedicated carrier, carrying the carrier to the first rotation chamber 140 and detaching the processing substrate SUB from the carrier carried out of the first rotation chamber 140.

The evaporation portion 150 comprises a first chamber group 150A and a second chamber group 150B. The first chamber group 150A comprises a plurality of evaporation chambers 151 to 155 which are arranged in line in a first conveyance direction TA in which the processing substrate SUB is conveyed. These evaporation chambers 151 to 155 are connected to each other. The second chamber group 150B comprises a plurality of evaporation chambers 156 to 160 which are arranged in line in a second conveyance direction TB which is the opposite direction of the first conveyance direction TA. These evaporation chambers 156 to 160 are connected to each other.

In the example shown in the figure, the evaporation portion 150 comprises 10 evaporation chambers 151 to 160. These 10 evaporation chambers 151 to 160 are arrayed in a matrix of 5×2.

The evaporation chamber 151 is configured to form the hole injection layer HIL1.

The evaporation chamber 152 is configured to form the hole transport layer HTL1.

The evaporation chamber 153 is configured to form the electron blocking layer EBL1.

The evaporation chamber 154 is configured to form the light emitting layer EM1.

The evaporation chamber 155 is configured to form the hole blocking layer HBL1.

The evaporation chamber 156 is configured to form the n-type charge generation layer nCGL1.

The evaporation chamber 157 is configured to form the p-type charge generation layer pCGL1.

The evaporation chamber 158 is configured to form the electron transport layer ETL1.

The evaporation chamber 159 is configured to form the electron injection layer EIL1.

The evaporation chamber 160 is configured to form the upper electrode UE1.

The first rotation chamber 140 is connected to the evaporation chamber 151 located at the most upstream position in the first conveyance direction TA in the first chamber group 150A and the evaporation chamber 160 located at the most downstream position in the second conveyance direction TB in the second chamber group 150B. The first rotation chamber 140 comprises a mechanism for rotating the processing substrate SUB so as to carry the processing substrate SUB carried out of the evaporation chamber 160 into the evaporation chamber 151.

The second rotation chamber 170 is connected to the evaporation chamber 155 located at the most downstream position in the first conveyance direction TA in the first chamber group 150A and the evaporation chamber 156 located at the most upstream position in the second conveyance direction TB in the second chamber group 150B. The second rotation chamber 170 comprises a mechanism for rotating the processing substrate SUB so as to carry the processing substrate SUB carried out of the evaporation chamber 155 into the evaporation chamber 156.

In the configuration example shown in FIG. 12, for example, the evaporation chamber 151 corresponds to a first evaporation chamber. The evaporation chamber 160 corresponds to a second evaporation chamber. The evaporation chamber 155 corresponds to a third evaporation chamber. The evaporation chamber 156 corresponds to a fourth evaporation chamber.

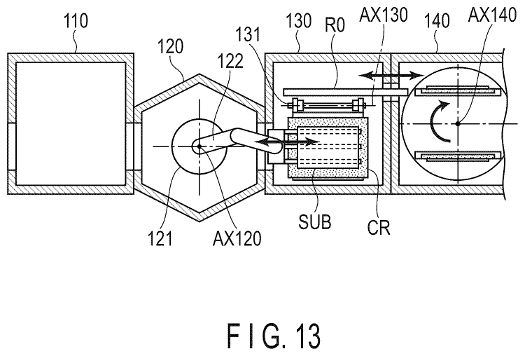

FIG. 13 is a diagram for explaining the conveyance chamber 120 shown in FIG. 12.

The conveyance chamber 120 comprises a substrate conveyance robot 121. The substrate conveyance robot 121 is configured to rotate about a rotation axis AX120. For example, the rotation axis AX120 is parallel to the normal relative to the horizontal plane. An arm 122 provided in the substrate conveyance robot 121 can freely expand and contract and is configured to support the processing substrate SUB in the distal end portion.

The substrate conveyance robot 121 comprising this configuration firstly inserts the distal end portion of the arm 122 into the load lock chamber 110, supports the processing substrate SUB and draws the processing substrate SUB into the conveyance chamber 120. Subsequently, the substrate conveyance robot 121 rotates 180° about the rotation axis AX120 in the horizontal plane, inserts the distal end portion of the arm 122 into the substrate attachment/detachment chamber 130, places the processing substrate SUB on a carrier CR and pulls back the arm 122. By this process, the processing substrate SUB is placed on the carrier CR. The processing substrate SUB is secured to the carrier CR by an electrostatic chuck. At this time, the processing substrate SUB and the carrier CR are parallel to the horizontal plane.

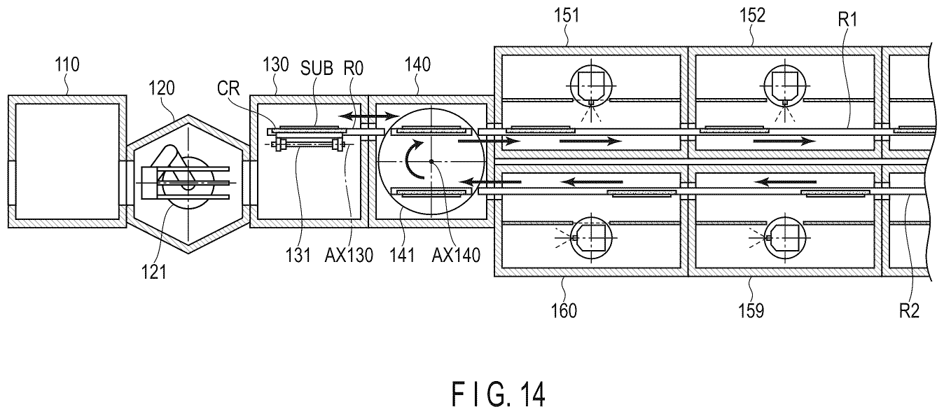

FIG. 14 is a diagram for explaining the substrate attachment/detachment chamber 130 and the first rotation chamber 140 shown in FIG. 12.

A conveyance rail R0 extends over the substrate attachment/detachment chamber 130 and the first rotation chamber 140 and is configured to convey the carrier CR between the substrate attachment/detachment chamber 130 and the first rotation chamber 140.

The substrate attachment/detachment chamber 130 comprises a longitudinal raising mechanism 131. The longitudinal raising mechanism 131 is configured to rotate about a rotation axis AX130. The rotation axis AX130 is parallel to the horizontal plane.

The longitudinal raising mechanism 131 rotates 90° about the rotation axis AX130 and perpendicularly raises the processing substrate SUB secured to the carrier CR. Subsequently, the longitudinal raising mechanism 131 places the carrier CR on the conveyance rail R0. Subsequently, the carrier CR and the processing substrate SUB are conveyed to the first rotation chamber 140 along the conveyance rail R0.

The longitudinal raising mechanism 131 receives the carrier CR conveyed from the first rotation chamber 140, rotates 90° about the rotation axis AX130 and causes the processing substrate SUB secured to the carrier CR to be parallel to the horizontal plane. Subsequently, the processing substrate SUB is released from the secured state applied by the electrostatic chuck and is carried out of the substrate attachment/detachment chamber 130 by the substrate conveyance robot 121.

The first rotation chamber 140 comprises a rotation mechanism 141. The rotation mechanism 141 is configured to rotate about a rotation axis AX140. The rotation axis AX140 is parallel to the normal relative to the horizontal plane.

When the processing substrate SUB and the carrier CR are carried out of the evaporation chamber 160, the rotation mechanism 141 rotates 180° about the rotation axis AX140 in the horizontal plane. Subsequently, the processing substrate SUB and the carrier CR are carried out to the evaporation chamber 151. Alternatively, the processing substrate SUB and the carrier CR are carried out to the substrate attachment/detachment chamber 130.

It should be noted that the second rotation chamber 170 comprises a rotation mechanism similar to that of the first rotation chamber 140.

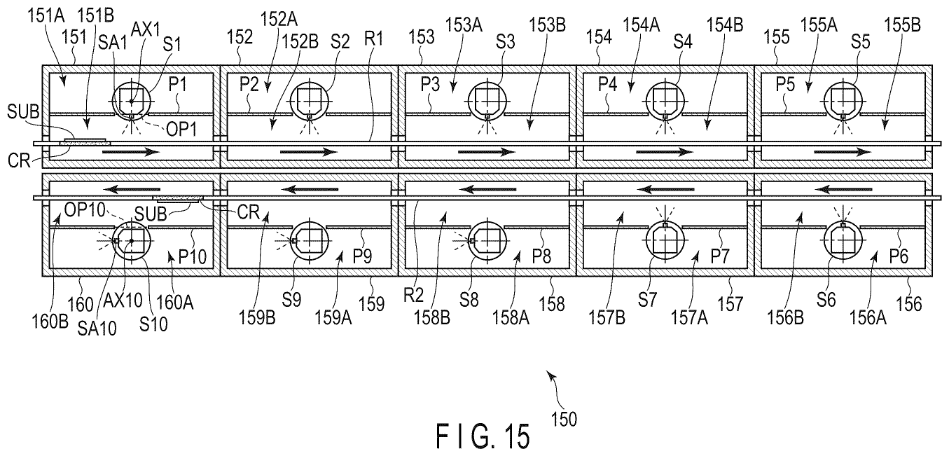

FIG. 15 is a diagram for explaining the evaporation portion 150 shown in FIG. 12.

A first conveyance rail R1 extends from the evaporation chamber 151 to the evaporation chamber 155 and is configured to convey the carrier CR to which the processing substrate SUB is attached.

A second conveyance rail R2 extends from the evaporation chamber 156 to the evaporation chamber 160 and is configured to convey the carrier CR to which the processing substrate SUB is attached.

Each of the evaporation chambers 151 to 160 comprises an evaporation source and a partition plate.

Specifically, the evaporation chamber 151 comprises an evaporation source S1 and a partition plate P1. The partition plate P1 partitions the evaporation chamber 151 into a first space 151A and a second space 151B. The evaporation source S1 is accommodated in the first space 151A. The second space 151B is a space in which the processing substrate SUB is conveyed together with the carrier CR. In the second space 151B, the first conveyance rail R1 is provided. The evaporation source S1 is configured to emit a material for forming the hole injection layer HIL1.

The evaporation chamber 152 comprises an evaporation source S2 and a partition plate P2. The evaporation source S2 is accommodated in a first space 152A and is configured to emit a material for forming the hole transport layer HTL1.

The evaporation chamber 153 comprises an evaporation source S3 and a partition plate P3. The evaporation source S3 is accommodated in a first space 153A and is configured to emit a material for forming the electron blocking layer EBL1.

The evaporation chamber 154 comprises an evaporation source S4 and a partition plate P4. The evaporation source S4 is accommodated in a first space 154A and is configured to emit a material for forming the light emitting layer EM1.

The evaporation chamber 155 comprises an evaporation source S5 and a partition plate P5. The evaporation source S5 is accommodated in a first space 155A and is configured to emit a material for forming the hole blocking layer HBL1.

The first conveyance rail R1 is provided in the second spaces 151B to 155B of the respective evaporation chambers 151 to 155. By this configuration, the carrier CR is successively conveyed from the evaporation chamber 151 to the evaporation chamber 155.

The evaporation chamber 156 comprises an evaporation source S6 and a partition plate P6. The evaporation source S6 is accommodated in a first space 156A and is configured to emit a material for forming the n-type charge generation layer nCGL1.

The evaporation chamber 157 comprises an evaporation source S7 and a partition plate P7. The evaporation source S7 is accommodated in a first space 157A and is configured to emit a material for forming the p-type charge generation layer pCGL1.

The evaporation chamber 158 comprises an evaporation source S8 and a partition plate P8. The evaporation source S8 is accommodated in a first space 158A and is configured to emit a material for forming the electron transport layer ETL1.

The evaporation chamber 159 comprises an evaporation source S9 and a partition plate P9. The evaporation source S9 is accommodated in a first space 159A and is configured to emit a material for forming the electron injection layer EIL1.

The evaporation chamber 160 comprises an evaporation source S10 and a partition plate P10. The evaporation source S10 is accommodated in a first space 160A and is configured to emit a material for forming the upper electrode UE1 (for example, a mixture of magnesium and silver).

The second conveyance rail R2 is provided in the second spaces 156B to 160B of the respective evaporation chambers 156 to 160. By this configuration, the carrier CR is successively conveyed from the evaporation chamber 156 to the evaporation chamber 160.

Each of the evaporation sources S1 to S10 is configured to heat and vaporize a material and continuously emit the material while the evaporation portion 150 operates. The materials emitted from the evaporation sources S1 to S10 are different from each other. In a mode in which the emitted material is not deposited on the processing substrate SUB, the discharge port of the evaporation source faces the first space. In a mode in which the emitted material is deposited on the processing substrate SUB, the discharge port of the evaporation source faces the second space.

For example, in the evaporation chamber 151, the evaporation source S1 is configured to rotate about a rotation axis AX1. The evaporation source S1 extends along the rotation axis AX1. The partition plate P1 comprises an opening OP1 shown by the dotted line. The opening OP1 faces the evaporation source S1.

In the example shown in the figure, the evaporation source S1 is set to a mode in which the emitted material is deposited on the processing substrate SUB, and a discharge port SA1 faces the second space 151B. By this configuration, the material emitted from the evaporation source S1 is deposited on the processing substrate SUB which is conveyed together with the carrier CR.

For example, in the evaporation chamber 160, the evaporation source S10 is configured to rotate about a rotation axis AX10. The evaporation source S10 extends along the rotation axis AX10. The partition plate P10 comprises an opening OP10 shown by the dotted line. The opening OP10 faces the evaporation source S10.

In the example shown in the figure, the evaporation source S10 is set to a mode in which the emitted material is not deposited on the processing substrate SUB, and a discharge port SA10 faces the first space 160A. By this configuration, the material emitted from the evaporation source S10 is not deposited on the processing substrate SUB which is conveyed together with the carrier CR.

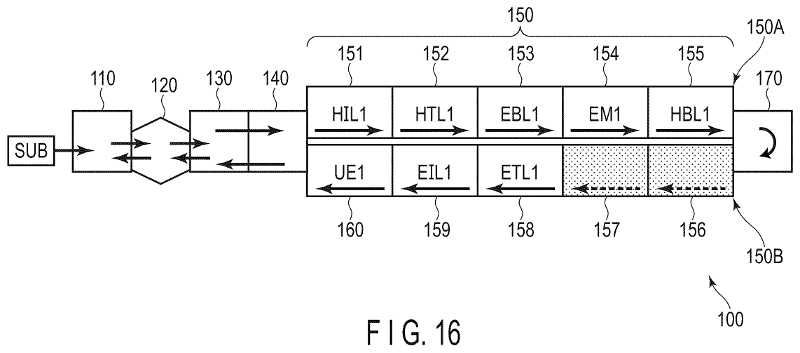

Now, this specification explains the process of forming the organic layer OR1 and the upper electrode UE1 of the display element 201 shown in FIG. 10 by the evaporation device 100 shown in FIG. 12 with reference to FIG. 16.

First, after the processing substrate SUB explained with reference to FIG. 5 is prepared, the processing substrate SUB is put in the load lock chamber 110 of the evaporation device 100 without providing a fine mask.

The processing substrate SUB passes through the first rotation chamber 140 after going through the conveyance chamber 120 and the substrate attachment/detachment chamber 130. Subsequently, the processing substrate SUB goes through the first chamber group 150A, is rotated 180° in the second rotation chamber 170 and goes through the second chamber group 150B.

When the processing substrate SUB goes through the first chamber group 150A, the hole injection layer HIL1 is formed on the lower electrode LE1 in the evaporation chamber 151, and the hole transport layer HTL1 is formed on the hole injection layer HIL1 in the evaporation chamber 152, and the electron blocking layer EBL1 is formed on the hole transport layer HTL1 in the evaporation chamber 153, and the light emitting layer EM1 is formed on the electron blocking layer EBL1 in the evaporation chamber 154, and the hole blocking layer HBL1 is formed on the light emitting layer EM1 in the evaporation chamber 155.

When the processing substrate SUB goes through the second chamber group 150B, the evaporation chambers 156 and 157 are set to a mode in which the materials emitted from the evaporation sources are not deposited on the processing substrate SUB. Thus, the processing substrate SUB passes through the evaporation chambers 156 and 157 without the deposition of the materials.

Subsequently, the electron transport layer ETL1 is formed on the hole blocking layer HBL1 in the evaporation chamber 158. The electron injection layer EIL1 is formed on the electron transport layer ETL1 in the evaporation chamber 159. The upper electrode UE1 is formed on the electron injection layer EIL1 in the evaporation chamber 160.

Subsequently, the processing substrate SUB passes through the first rotation chamber 140, the substrate attachment/detachment chamber 130 and the conveyance chamber 120 in order, is returned to the load lock chamber 110 and is carried out of the evaporation device 100.

In the processing substrate SUB carried out of the evaporation device 100, as explained with reference to FIG. 6, the organic layer OR1 formed on the partition 6 is spaced apart from the organic layer OR1 formed on the lower electrode LE1 in the aperture AP1. The upper electrode UE1 formed on the partition 6 is spaced apart from the upper electrode UE1 formed immediately above the lower electrode LE1.

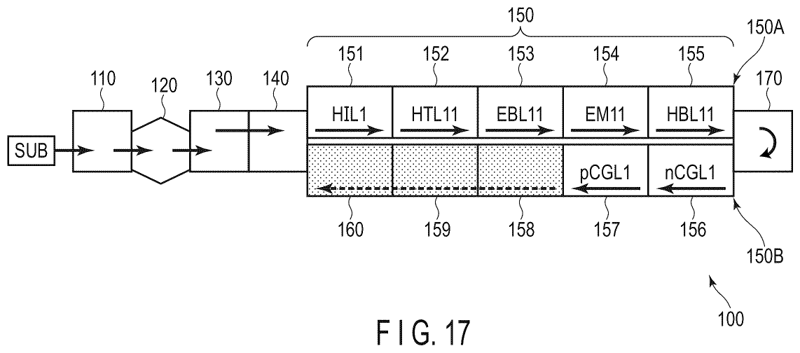

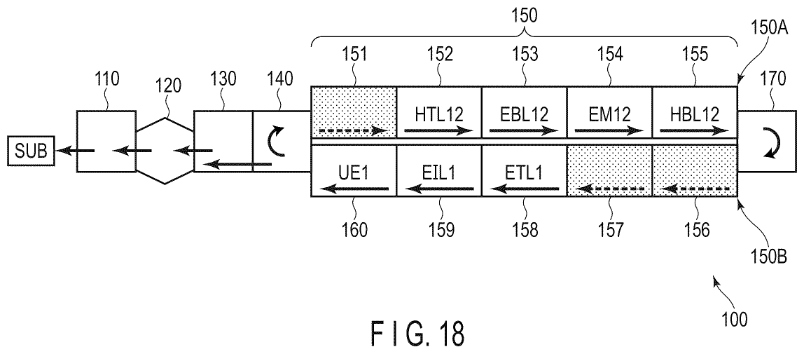

Now, this specification explains the process of forming the organic layer OR1 and the upper electrode UE1 of the display element 201 shown in FIG. 11 by the evaporation device 100 shown in FIG. 12 with reference to FIG. 17 and FIG. 18.

First, as shown in FIG. 17, the processing substrate SUB is put in the load lock chamber 110 of the evaporation device 100 without providing a fine mask.

The processing substrate SUB passes through the first rotation chamber 140 after going through the conveyance chamber 120 and the substrate attachment/detachment chamber 130. Subsequently, the processing substrate SUB goes through the first chamber group 150A, is rotated 180° in the second rotation chamber 170 and goes through the second chamber group 150B.

When the processing substrate SUB goes through the first chamber group 150A, the hole injection layer HIL1 is formed on the lower electrode LE1 in the evaporation chamber 151, and the hole transport layer HTL11 is formed on the hole injection layer HIL1 in the evaporation chamber 152, and the electron blocking layer EBL11 is formed on the hole transport layer HTL11 in the evaporation chamber 153, and the light emitting layer EM11 is formed on the electron blocking layer EBL11 in the evaporation chamber 154, and the hole blocking layer HBL11 is formed on the light emitting layer EM11 in the evaporation chamber 155.

When the processing substrate SUB goes through the second chamber group 150B, the n-type charge generation layer nCGL1 is formed on the hole blocking layer HBL11 in the evaporation chamber 156, and the p-type charge generation layer pCGL1 is formed on the n-type charge generation layer nCGL1 in the evaporation chamber 157.

The evaporation chambers 158 and 160 are set to a mode in which the materials emitted from the evaporation sources are not deposited on the processing substrate SUB. Thus, the processing substrate SUB passes through the evaporation chambers 158 to 160 without the deposition of the materials.

Subsequently, as shown in FIG. 18, the processing substrate SUB is rotated 180° in the first rotation chamber 140, goes through the first chamber group 150A, is rotated 180° in the second rotation chamber 170 and goes through the second chamber group 150B.

When the processing substrate SUB goes through the first chamber group 150A, the evaporation chamber 151 is set to a mode in which the material emitted from the evaporation source is not deposited on the processing substrate SUB. Thus, the processing substrate SUB passes through the evaporation chamber 151 without the deposition of the material.

Subsequently, the hole transport layer HTL12 is formed on the p-type charge generation layer pCGL1 in the evaporation chamber 152. The electron blocking layer EBL12 is formed on the hole transport layer HTL12 in the evaporation chamber 153. The light emitting layer EM12 is formed on the electron blocking layer EBL12 in the evaporation chamber 154. The hole blocking layer HBL12 is formed on the light emitting layer EM12 in the evaporation chamber 155.

When the processing substrate SUB goes through the second chamber group 150B, the evaporation chambers 156 and 157 are set to a mode in which the materials emitted from the evaporation sources are not deposited on the processing substrate SUB. Thus, the processing substrate SUB passes through the evaporation chambers 156 and 157 without the deposition of the materials.

Subsequently, the electron transport layer ETL1 is formed on the hole blocking layer HBL12 in the evaporation chamber 158. The electron injection layer EIL1 is formed on the electron transport layer ETL1 in the evaporation chamber 159. The upper electrode UE1 is formed on the electron injection layer EIL1 in the evaporation chamber 160.

Subsequently, the processing substrate SUB passes through the first rotation chamber 140, the substrate attachment/detachment chamber 130 and the conveyance chamber 120 in order, is returned to the load lock chamber 110 and is carried out of the evaporation device 100.

In the processing substrate SUB carried out of the evaporation device 100, as explained with reference to FIG. 6, the organic layer OR1 formed on the partition 6 is spaced apart from the organic layer OR1 formed on the lower electrode LE1 in the aperture AP1. The upper electrode UE1 formed on the partition 6 is spaced apart from the upper electrode UE1 formed immediately above the lower electrode LE1 in the aperture AP1.

In the example shown in the figures, the hole transport layer HTL11 corresponds to a first hole transport layer, and the hole transport layer HTL12 corresponds to a second hole transport layer, and the hole transport layers HTL11 and HTL12 are formed of the same material in the same evaporation chamber 152.

The electron blocking layer EBL11 corresponds to a first electron blocking layer. The electron blocking layer EBL12 corresponds to a second electron blocking layer. The electron blocking layers EBL11 and EBL12 are formed of the same material in the same evaporation chamber 153.

The light emitting layer EM11 corresponds to a first light emitting layer. The light emitting layer EM12 corresponds to a second light emitting layer. The light emitting layers EM11 and EM12 are formed of the same material in the same evaporation chamber 154.

The hole blocking layer HBL11 corresponds to a first hole blocking layer. The hole blocking layer HBL12 corresponds to a second hole blocking layer. The hole blocking layers HBL11 and HBL12 are formed of the same material in the same evaporation chamber 154.

It should be noted that, in the process of forming the organic layer OR1 and the upper electrode UE1 explained with reference to FIG. 16 to FIG. 18, the conveyance speed of the processing substrate SUB in the first chamber group 150A and the second chamber group 150B is constant.

As explained above, according to the present embodiment, in a single evaporation device 100, both a display element comprising a single configuration and a display element comprising a tandem configuration can be easily formed. Thus, even if a large difference is generated in the manufacturing ratio between the products comprising a tandem configuration and the products comprising a single configuration, the reduction in the rate of operation of the evaporation device 100 is prevented.

Further, as the evaporation device 100 comprises both the function of depositing a material while rotating the evaporation portion 150 a plurality of times and a mode setting function which enables the user to select the presence or absence of the deposition of the emitted material, a variety of tandem configurations can be realized.

When a display element comprising a tandem configuration is formed, the same functional layers can be formed in a single evaporation chamber. Thus, compared to an evaporation device comprising evaporation chambers for forming respective layers, the number of evaporation chambers is reduced. Thus, the installation cost is reduced, and further, the installation space or scale is reduced.

Now, this specification explains another evaporation device for forming the organic layer and the upper electrode of a display element. Here, for example, this specification explains an evaporation device 100 for forming the organic layer OR1 and the upper electrode UE1 of the display element 201. It should be noted that an evaporation device for forming the organic layer OR2 and the upper electrode UE2 of the display element 202 and an evaporation device for forming the organic layer OR3 and the upper electrode UE3 of the display element 203 can be configured in the same manner as the evaporation device 100 explained here.

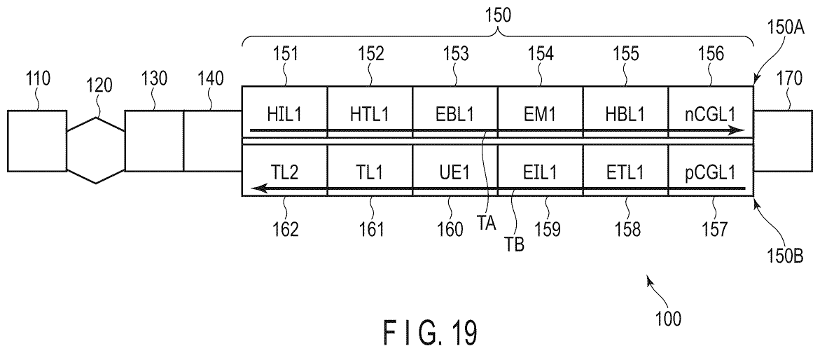

FIG. 19 is a diagram for explaining another configuration example of the evaporation device 100. The evaporation device 100 is applied to the formation of the organic layer OR1 and the upper electrode UE1 in the process of forming the first thin film 31 explained with reference to FIG. 4 and FIG. 6.

The example shown in FIG. 19 is different from the example shown in FIG. 12 in respect that the evaporation portion 150 further comprises an evaporation chamber 161 for forming the first transparent layer TL1 and an evaporation chamber 162 for forming the second transparent layer TL2. As the other configurations of the evaporation device 100 are the same as the example shown in FIG. 12, the detailed description thereof is omitted by adding the same reference numbers.

The evaporation portion 150 comprises a first chamber group 150A and a second chamber group 150B. The first chamber group 150A comprises a plurality of evaporation chambers 151 to 156 which are arranged in line in the first conveyance direction TA in which the processing substrate SUB is conveyed. These evaporation chambers 151 to 156 are connected to each other. The second chamber group 150B comprises a plurality of evaporation chambers 157 to 162 which are arranged in line in the second conveyance direction TB which is the opposite direction of the first conveyance direction TA. These evaporation chambers 157 to 162 are connected to each other.

In the example shown in the figure, the evaporation portion 150 comprises 12 evaporation chambers 151 to 162. These 12 evaporation chambers 151 to 162 are arrayed in a matrix of 6×2.

The evaporation chamber 151 is configured to form the hole injection layer HIL1.

The evaporation chamber 152 is configured to form the hole transport layer HTL1.

The evaporation chamber 153 is configured to form the electron blocking layer EBL1.

The evaporation chamber 154 is configured to form the light emitting layer EM1.

The evaporation chamber 155 is configured to form the hole blocking layer HBL1.

The evaporation chamber 156 is configured to form the n-type charge generation layer nCGL1.

The evaporation chamber 157 is configured to form the p-type charge generation layer pCGL1.

The evaporation chamber 158 is configured to form the electron transport layer ETL1.

The evaporation chamber 159 is configured to form the electron injection layer EIL1.

The evaporation chamber 160 is configured to form the upper electrode UE1.

The evaporation chamber 161 is configured to form the first transparent layer TL1.

The evaporation chamber 162 is configured to form the second transparent layer TL2. For example, the evaporation chamber 162 is configured to emit lithium fluoride as the material for forming the second transparent layer TL2.

The first rotation chamber 140 is connected to the evaporation chamber 151 located at the most upstream position in the first conveyance direction TA in the first chamber group 150A and the evaporation chamber 162 located at the most downstream position in the second conveyance direction TB in the second chamber group 150B. The first rotation chamber 140 comprises a mechanism for rotating the processing substrate SUB so as to carry the processing substrate SUB carried out of the evaporation chamber 162 into the evaporation chamber 151.

The second rotation chamber 170 is connected to the evaporation chamber 156 located at the most downstream position in the first conveyance direction TA in the first chamber group 150A and the evaporation chamber 157 located at the most upstream position in the second conveyance direction TB in the second chamber group 150B. The second rotation chamber 170 comprises a mechanism for rotating the processing substrate SUB so as to carry the processing substrate SUB carried out of the evaporation chamber 156 into the evaporation chamber 157.

In the configuration example shown in FIG. 19, for example, the evaporation chamber 151 corresponds to the first evaporation chamber. The evaporation chamber 162 corresponds to the second evaporation chamber. The evaporation chamber 156 corresponds to the third evaporation chamber. The evaporation chamber 157 corresponds to the fourth evaporation chamber.

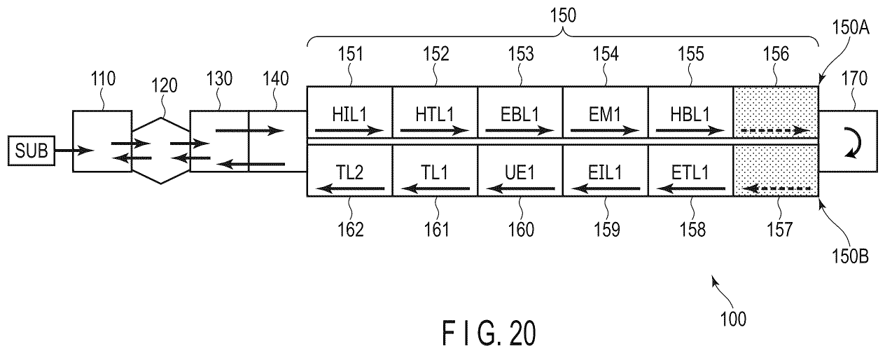

Now, this specification explains the process of forming the organic layer OR1, the upper electrode UE1 and the cap layer CP1 of the display element 201 shown in FIG. 10 by the evaporation device 100 shown in FIG. 19 with reference to FIG. 20.

First, after the processing substrate SUB explained with reference to FIG. 5 is prepared, the processing substrate SUB is put in the load lock chamber 110 of the evaporation device 100 without providing a fine mask.

The processing substrate SUB passes through the first rotation chamber 140 after going through the conveyance chamber 120 and the substrate attachment/detachment chamber 130. Subsequently, the processing substrate SUB goes through the first chamber group 150A, is rotated 180° in the second rotation chamber 170 and goes through the second chamber group 150B.

When the processing substrate SUB goes through the first chamber group 150A, the hole injection layer HIL1 is formed on the lower electrode LE1 in the evaporation chamber 151, and the hole transport layer HTL1 is formed on the hole injection layer HIL1 in the evaporation chamber 152, and the electron blocking layer EBL1 is formed on the hole transport layer HTL1 in the evaporation chamber 153, and the light emitting layer EM1 is formed on the electron blocking layer EBL1 in the evaporation chamber 154, and the hole blocking layer HBL1 is formed on the light emitting layer EM1 in the evaporation chamber 155.

The evaporation chamber 156 is set to a mode in which the material emitted from the evaporation source is not deposited on the processing substrate SUB. Thus, the processing substrate SUB passes through the evaporation chamber 156 without the deposition of the material.

When the processing substrate SUB goes through the second chamber group 150B, the evaporation chamber 157 is set to a mode in which the material emitted from the evaporation source is not deposited on the processing substrate SUB. Thus, the processing substrate SUB passes through the evaporation chamber 157 without the deposition of the material.

Subsequently, the electron transport layer ETL1 is formed on the hole blocking layer HBL1 in the evaporation chamber 158. The electron injection layer EIL1 is formed on the electron transport layer ETL1 in the evaporation chamber 159. The upper electrode UE1 is formed on the electron injection layer EIL1 in the evaporation chamber 160. The first transparent layer TL1 is formed on the upper electrode UE1 in the evaporation chamber 161. The second transparent layer TL2 is formed on the first transparent layer TL1 in the evaporation chamber 162.

Subsequently, the processing substrate SUB passes through the first rotation chamber 140, the substrate attachment/detachment chamber 130 and the conveyance chamber 120 in order, is returned to the load lock chamber 110 and is carried out of the evaporation device 100.

In the processing substrate SUB carried out of the evaporation device 100, as explained with reference to FIG. 6, the organic layer OR1 formed on the partition 6 is spaced apart from the organic layer OR1 formed on the lower electrode LE1 in the aperture AP1. The upper electrode UE1 formed on the partition 6 is spaced apart from the upper electrode UE1 formed immediately above the lower electrode LE1. The first and second transparent layers TL1 and TL2 formed on the partition 6 are spaced apart from the first and second transparent layers TL1 and TL2 formed immediately above the lower electrode LE1.

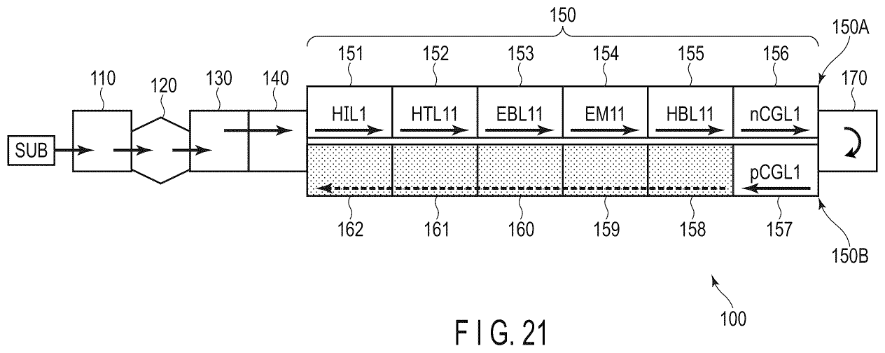

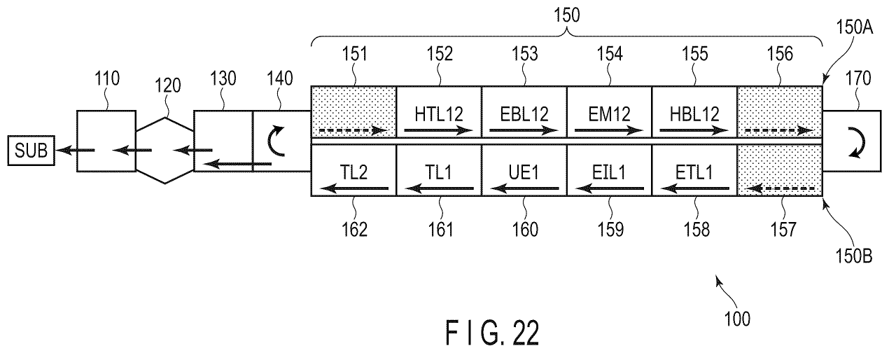

Now, this specification explains the process of forming the organic layer OR1, the upper electrode UE1 and the cap layer CP1 of the display element 201 shown in FIG. 11 by the evaporation device 100 shown in FIG. 19 with reference to FIG. 21 and FIG. 22.

First, as shown in FIG. 21, the processing substrate SUB is put in the load lock chamber 110 of the evaporation device 100 without providing a fine mask.

The processing substrate SUB passes through the first rotation chamber 140 after going through the conveyance chamber 120 and the substrate attachment/detachment chamber 130. Subsequently, the processing substrate SUB goes through the first chamber group 150A, is rotated 180° in the second rotation chamber 170 and goes through the second chamber group 150B.

When the processing substrate SUB goes through the first chamber group 150A, the hole injection layer HIL1 is formed on the lower electrode LE1 in the evaporation chamber 151, and the hole transport layer HTL11 is formed on the hole injection layer HIL1 in the evaporation chamber 152, and the electron blocking layer EBL11 is formed on the hole transport layer HTL11 in the evaporation chamber 153, and the light emitting layer EM11 is formed on the electron blocking layer EBL11 in the evaporation chamber 154, and the hole blocking layer HBL11 is formed on the light emitting layer EM11 in the evaporation chamber 155, and the n-type charge generation layer nCGL1 is formed on the hole blocking layer HBL11 in the evaporation chamber 156.

When the processing substrate SUB goes through the second chamber group 150B, the p-type charge generation layer pCGL1 is formed on the n-type charge generation layer nCGL1 in the evaporation chamber 157.

The evaporation chambers 158 to 162 are set to a mode in which the materials emitted from the evaporation sources are not deposited on the processing substrate SUB. Thus, the processing substrate SUB passes through the evaporation chambers 158 to 162 without the deposition of the materials.

Subsequently, as shown in FIG. 22, the processing substrate SUB is rotated 180° in the first rotation chamber 140, goes through the first chamber group 150A, is rotated 180° in the second rotation chamber 170 and goes through the second chamber group 150B.

When the processing substrate SUB goes through the first chamber group 150A, the evaporation chamber 151 is set to a mode in which the material emitted from the evaporation source is not deposited on the processing substrate SUB. Thus, the processing substrate SUB passes through the evaporation chamber 151 without the deposition of the material.

Subsequently, the hole transport layer HTL12 is formed on the p-type charge generation layer pCGL1 in the evaporation chamber 152. The electron blocking layer EBL12 is formed on the hole transport layer HTL12 in the evaporation chamber 153. The light emitting layer EM12 is formed on the electron blocking layer EBL12 in the evaporation chamber 154. The hole blocking layer HBL12 is formed on the light emitting layer EM12 in the evaporation chamber 155.

The evaporation chamber 156 is set to a mode in which the material emitted from the evaporation source is not deposited on the processing substrate SUB. Thus, the processing substrate SUB passes through the evaporation chamber 156 without the deposition of the material.

When the processing substrate SUB goes through the second chamber group 150B, the evaporation chamber 157 is set to a mode in which the material emitted from the evaporation source is not deposited on the processing substrate SUB. Thus, the processing substrate SUB passes through the evaporation chamber 157 without the deposition of the material.

Subsequently, the electron transport layer ETL1 is formed on the hole blocking layer HBL12 in the evaporation chamber 158. The electron injection layer EIL1 is formed on the electron transport layer ETL1 in the evaporation chamber 159. The upper electrode UE1 is formed on the electron injection layer EIL1 in the evaporation chamber 160. The first transparent layer TL1 is formed on the upper electrode UE1 in the evaporation chamber 161. The second transparent layer TL2 is formed on the first transparent layer TL1 in the evaporation chamber 162.

Subsequently, the processing substrate SUB passes through the first rotation chamber 140, the substrate attachment/detachment chamber 130 and the conveyance chamber 120 in order, is returned to the load lock chamber 110 and is carried out of the evaporation device 100.

In the processing substrate SUB carried out of the evaporation device 100, as explained with reference to FIG. 6, the organic layer OR1 formed on the partition 6 is spaced apart from the organic layer OR1 formed on the lower electrode LE1 in the aperture AP1. The upper electrode UE1 formed on the partition 6 is spaced apart from the upper electrode UE1 formed immediately above the lower electrode LE1. The first and second transparent layers TL1 and TL2 formed on the partition 6 are spaced apart from the first and second transparent layers TL1 and TL2 formed immediately above the lower electrode LE1.

In the example shown in the figures, the hole transport layer HTL11 corresponds to the first hole transport layer, and the hole transport layer HTL12 corresponds to the second hole transport layer, and the hole transport layers HTL11 and HTL12 are formed of the same material in the same evaporation chamber 152.

The electron blocking layer EBL11 corresponds to the first electron blocking layer. The electron blocking layer EBL12 corresponds to the second electron blocking layer. The electron blocking layers EBL11 and EBL12 are formed of the same material in the same evaporation chamber 153.

The light emitting layer EM11 corresponds to the first light emitting layer. The light emitting layer EM12 corresponds to the second light emitting layer. The light emitting layers EM11 and EM12 are formed of the same material in the same evaporation chamber 154.

The hole blocking layer HBL11 corresponds to the first hole blocking layer. The hole blocking layer HBL12 corresponds to the second hole blocking layer. The hole blocking layers HBL11 and HBL12 are formed of the same material in the same evaporation chamber 154.

It should be noted that, in the process of forming the organic layer OR1, the upper electrode UE1 and the cap layer CP1 explained with reference to FIG. 20 to FIG. 22, the conveyance speed of the processing substrate SUB in the first chamber group 150A and the second chamber group 150B is constant.

From this evaporation device, effects similar to those of the evaporation device described above can be obtained. In addition, the organic layer, the upper electrode and the cap layer can be successively deposited.

As explained above, the embodiments can provide an evaporation device and an evaporation method such that the cost and the installation space can be reduced.

All of the evaporation devices and evaporation methods that can be implemented by a person of ordinary skill in the art through arbitrary design changes to the evaporation device and evaporation method described above as each embodiment of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is:

1. An evaporation device comprising:
a first chamber group comprising a plurality of evaporation chambers which are arranged in line in a first conveyance direction in which a processing substrate is conveyed;
a second chamber group comprising a plurality of evaporation chambers which are arranged in line in a second conveyance direction which is an opposite direction of the first conveyance direction;
a first rotation chamber which is connected to a first evaporation chamber located at a most upstream position in the first conveyance direction in the first chamber group and a second evaporation chamber located at a most downstream position in the second conveyance direction in the second chamber group, and rotates the processing substrate carried out of the second evaporation chamber to carry the processing substrate into the first evaporation chamber; and
a second rotation chamber which is connected to a third evaporation chamber located at a most downstream position in the first conveyance direction in the first chamber group and a fourth evaporation chamber located at a most upstream position in the second conveyance direction in the second chamber group, and rotates the processing substrate carried out of the third evaporation chamber to carry the processing substrate into the fourth evaporation chamber.

2. The evaporation device of claim 1, further comprising a substrate attachment/detachment chamber connected to the first rotation chamber, wherein
the substrate attachment/detachment chamber is configured to attach the processing substrate carried into the substrate attachment/detachment chamber to a carrier, carry the carrier to the first rotation chamber, and detach the processing substrate from the carrier carried out of the first rotation chamber.

3. The evaporation device of claim 2, further comprising:
a first conveyance rail extending from the first evaporation chamber to the third evaporation chamber and configured to convey the carrier; and
a second conveyance rail extending from the second evaporation chamber to the fourth evaporation chamber and configured to convey the carrier.

4. The evaporation device of claim 3, wherein
each of the evaporation chambers comprises an evaporation source configured to emit a material from a discharge port, and a partition plate which partitions the evaporation chamber into a first space in which the evaporation source is accommodated and a second space in which the processing substrate is conveyed,
the first conveyance rail is provided in the second space of each of the evaporation chambers including the first evaporation chamber and the third evaporation chamber,
the second conveyance rail is provided in the second space of each of the evaporation chambers including the second evaporation chamber and the fourth evaporation chamber,
the partition plate comprises an opening facing the evaporation source, and
the evaporation source is configured such that the discharge port faces the first space in a mode in which the emitted material is not deposited on the processing substrate, and the discharge port faces the second space in a mode in which the emitted material is deposited on the processing substrate.

5. The evaporation device of claim 4, wherein
the evaporation sources provided in the respective evaporation chambers are configured to emit materials different from each other.

6. The evaporation device of claim 5, wherein
the material emitted from the evaporation source of the first evaporation chamber is a material for forming a hole injection layer.

7. The evaporation device of claim 6, wherein
the material emitted from the evaporation source of the second evaporation chamber is a mixture of magnesium and silver.

8. The evaporation device of claim 6, wherein
the material emitted from the evaporation source of the second evaporation chamber is lithium fluoride.

9. The evaporation device of claim 1, wherein
the first chamber group comprises the first evaporation chamber for forming a hole injection layer, an evaporation chamber for forming a hole transport layer, an evaporation chamber for forming an electron blocking layer, an evaporation chamber for forming a light emitting layer, and the third evaporation chamber for forming a hole blocking layer, and
the second chamber group comprises the fourth evaporation chamber for forming an n-type charge generation layer, an evaporation chamber for forming a p-type charge generation layer, an evaporation chamber for forming an electron transport layer, an evaporation chamber for forming an electron injection layer, and the second evaporation chamber for forming an upper electrode.

10. The evaporation device of claim 1, wherein
the first chamber group comprises the first evaporation chamber for forming a hole injection layer, an evaporation chamber for forming a hole transport layer, an evaporation chamber for forming an electron blocking layer, an evaporation chamber for forming a light emitting layer, an evaporation chamber for forming a hole blocking layer, and the third evaporation chamber for forming an n-type charge generation layer, and
the second chamber group comprises the fourth evaporation chamber for forming a p-type charge generation layer, an evaporation chamber for forming an electron transport layer, an evaporation chamber for forming an electron injection layer, an evaporation chamber for forming an upper electrode, an evaporation chamber for forming a first transparent layer, and the second evaporation chamber for forming a second transparent layer.

11. An evaporation method comprising:
preparing a processing substrate by forming a lower electrode above a substrate, forming a rib comprising an aperture overlapping the lower electrode, and forming a partition including a lower portion located on the rib and an upper portion located on the lower portion and protruding from a side surface of the lower portion; and
carrying the processing substrate in an evaporation device without providing a mask, forming an organic layer, forming an upper electrode on the organic layer, and carrying the processing substrate out of the evaporation device, wherein
in the evaporation device, the processing substrate which is carried in
passes through a first rotation chamber,
goes through a first chamber group comprising a plurality of evaporation chambers arranged in line in a first conveyance direction,
is rotated 180° in a second rotation chamber,
goes through a second chamber group comprising a plurality of evaporation chambers arranged in line in a second conveyance direction which is an opposite direction of the first conveyance direction,
is rotated 180° in the first rotation chamber,
goes through the first chamber group,
is rotated 180° in the second rotation chamber,
goes through the second chamber group, and
passes through the first rotation chamber and is carried out of the evaporation device, and
in the processing substrate which is carried out of the evaporation device, the organic layer and the upper electrode formed on the partition are spaced apart from the organic layer and the upper electrode formed on the lower electrode in the aperture.

12. The evaporation method of claim 11, further comprising:
when going through the first chamber group and the second chamber group,
forming a hole injection layer on the lower electrode;
forming a first hole transport layer on the hole injection layer;
forming a first electron blocking layer on the first hole transport layer;
forming a first light emitting layer on the first electron blocking layer;
forming a first hole blocking layer on the first light emitting layer;
forming an n-type charge generation layer on the first hole blocking layer;
forming a p-type charge generation layer on the n-type charge generation layer;
forming a second hole transport layer on the p-type charge generation layer;
forming a second electron blocking layer on the second hole transport layer;
forming a second light emitting layer on the second electron blocking layer;
forming a second hole blocking layer on the second light emitting layer;
forming an electron transport layer on the second hole blocking layer;
forming an electron injection layer on the electron transport layer; and
forming the upper electrode on the electron injection layer.

13. The evaporation method of claim 12, wherein
the first hole transport layer and the second hole transport layer are formed of a same material in a same evaporation chamber,
the first electron blocking layer and the second electron blocking layer are formed of a same material in a same evaporation chamber,
the first light emitting layer and the second light emitting layer are formed of a same material in a same evaporation chamber, and
the first hole blocking layer and the second hole blocking layer are formed of a same material in a same evaporation chamber.

14. The evaporation method of claim 12, further comprising:
when going through the second chamber group,
forming a first transparent layer on the upper electrode; and
forming a second transparent layer on the first transparent layer.

15. The evaporation method of claim 11, wherein
a conveyance speed of the processing substrate in the first chamber group and the second chamber group is constant.

16. The evaporation method of claim 11, wherein
when the processing substrate goes through the second chamber group, a material emitted from an evaporation source is not deposited on the processing substrate in at least one evaporation chamber.
